(19) United States
(12) Patent Application Publication
(10) Pub. No.: US 2024/0096956 A1
(43) Pub. Date: Mar. 21, 2024

(54) INTEGRATED CIRCUIT SEMICONDUCTOR DEVICE

(71) Applicant: Samsung Electronics Co., Ltd., Suwon-si (KR)

(72) Inventors: Hyungjoo Na, Suwon-si (KR); Woobin Song, Suwon-si (KR); Jinwook Yang, Suwon-si (KR); Cheoljin Yun, Suwon-si (KR); Dongkyu Lee, Suwon-si (KR); Yoshinao Harada, Suwon-si (KR)

(73) Assignee: Samsung Electronics Co., Ltd., Suwon-si (KR)

(21) Appl. No.: 18/370,663

(22) Filed: Sep. 20, 2023

(30) Foreign Application Priority Data
Sep. 21, 2022 (KR) 10-2022-0119536

(51) Int. Cl. H01L 29/06; H01L 29/08; H01L 29/10; H01L 29/49; H01L 29/66

(52) U.S. Cl. CPC H01L 29/0673; H01L 29/0847; H01L 29/1033; H01L 29/4933; H01L 29/66553

(57) ABSTRACT

An integrated circuit semiconductor device includes a nanosheet extending above a substrate in a first horizontal direction, a gate electrode extending in a second horizontal direction while surrounding the nanosheet with a gate insulating layer therebetween, a first source/drain region on a side of the nanosheet, and a second source/drain region on another side of the nanosheet, wherein the first source/drain region includes first silicide layers provided inward from surfaces of the nanosheet, first metal layers surrounding the nanosheet from upper and lower sides of the first silicide layers, and a first nanosheet region provided between the first silicide layers, wherein the second source/drain region includes second silicide layers formed inward from the surfaces of the nanosheet, second metal layers surrounding the nanosheet from upper and lower sides of the second silicide layers, and a second nanosheet region provided between the second silicide layers.

### CROSS-REFERENCE TO RELATED APPLICATION

This application is based on and claims priority under 35 U.S.C. § 119 to Korean Patent Application No. 10-2022-0119536, filed on Sep. 21, 2022, in the Korean Intellectual Property Office, the disclosure of which is incorporated by reference herein in its entirety.

### BACKGROUND

The disclosure relates to integrated circuit semiconductor devices, and more particularly, to integrated circuit semiconductor devices including three-dimensional transistors.

As the degree of integration of integrated circuit semiconductor devices increases, three-dimensional transistors may be employed to improve the electrical characteristics of integrated circuit semiconductor devices such as a short channel effect or current driving capability. It is needed to further improve the electrical characteristics of integrated circuit semiconductor devices including three-dimensional transistors.

### SUMMARY

Embodiments of the disclosure provide integrated circuit semiconductor devices that include three-dimensional transistors having low-contact-resistance source/drain regions.

According to an aspect of the disclosure, there is provided an integrated circuit semiconductor device including: a nanosheet provided on a substrate, the nanosheet extending in a first horizontal direction; a gate electrode including a first gate electrode portion provided on an upper side of the nanosheet and a second gate electrode portion provided on a lower side of the nanosheet, the gate electrode extending in a second horizontal direction that is perpendicular to the first horizontal direction; a gate insulating layer provided between the gate electrode and the nanosheet; a first source/drain region provided on a first side of the nanosheet corresponding to the gate electrode; and a second source/drain region provided on a second side of the nanosheet corresponding to the gate electrode, wherein the first source/drain region includes: first silicide layers including a first upper silicide layer provided on the nanosheet and extending inward from an upper surface of the nanosheet, and a first lower silicide layer on provided the nanosheet and extending inward from a lower surface of the nanosheet, a first upper metal layer provided on the first upper silicide layer and a first lower metal layer provided on the first lower silicide layer, and a first nanosheet region provided between the first upper silicide layer and the first lower silicide layer, wherein the second source/drain region includes: second silicide layers including a second upper silicide layer provided on the nanosheet and extending inward from the upper surface of the nanosheet, and a second lower silicide layer provided on the nanosheet and extending inward from the lower surface of the nanosheet, a second upper metal layer provided on the second upper silicide layer and a second lower metal layer provided on the second lower silicide layer, and a second nanosheet region provided between the second upper silicide layer and the second lower silicide layer.

The nanosheet may extend from the gate electrode to the first source/drain region in the first horizontal direction and extends from the gate electrode to the second source/drain region in a first reverse horizontal direction.

The nanosheet may include a single layer which continuously extends in the first horizontal direction.

The nanosheet may be spaced apart from a surface of the substrate, and a thickness of the nanosheet in a first vertical direction is greater than a thickness of the nanosheet in the second horizontal direction, the first vertical direction being perpendicular to the first and second horizontal directions.

The nanosheet may have a first thickness in a first region between the first gate electrode portion and the second gate electrode portion and a second thickness in a second region between the first upper silicide layer and the first lower silicide layer or between the second upper silicide layer and the second lower silicide layer, the first thickness being different from the second thickness.

Each of the first silicide layers and the second silicide layers may include metal silicide layers or polycide layers.

The first source/drain region further may include first metal liner layers provided on the first silicide layers, and the second source/drain region further includes second metal liner layers provided on the second silicide layers.

The integrated circuit semiconductor device may further include a first spacer provided between the gate electrode and the first source/drain region; and a second spacer provided between the gate electrode and the second source/drain region.

The integrated circuit semiconductor device may further include a through-electrode provided in the substrate and electrically connected to the first and second source/drain regions, and a backside power rail provided in a back surface of the substrate electrically connected to the through-electrode.

The integrated circuit semiconductor device may further include a first backside power rail provided in the substrate and electrically connected to the first and second source/drain regions, a through-electrode provided in the substrate and electrically connected to the first backside power rail, and a second backside power rail provided in a back surface of the substrate, and electrically connected to the through-electrode.

According to another aspect of the disclosure, there is provided an integrated circuit semiconductor device including: a plurality of nanosheets provided on a substrate, the plurality of nanosheets extending in a first horizontal direction and being spaced apart from a surface of the substrate and spaced apart from each other in a first vertical direction that is perpendicular to the first horizontal direction; a gate electrode including a plurality of gate electrode portions provided on the plurality of nanosheets, the gate electrode extending in a second horizontal direction that is perpendicular to the first horizontal direction; a plurality of gate insulating layers provided between the plurality of gate electrode portions and the plurality of nanosheets; a first source/drain region provided on a first side of the plurality of nanosheets corresponding to the gate electrode; and a second source/drain region provided on a second side of the plurality of nanosheets corresponding to the gate electrode, wherein the first source/drain region includes: first silicide layers including a first upper silicide layer provided on a first nanosheet, among the plurality of nanosheets, and extending inward from an upper surface of the first nanosheet, and a first lower silicide layer on provided the first nanosheet and extending inward from a lower surface of the first nanosheet, a first upper metal layer provided on the first upper silicide layer, a first lower metal layer provided on the first lower silicide layer, and a first nanosheet region provided between the first upper silicide layer and the first lower silicide layer, and wherein the second source/drain region includes: second silicide layers including a second upper silicide layer provided on the first nanosheet and extending inward from the upper surface of the first nanosheet, and a second lower silicide layer provided on the first nanosheet and extending inward from the lower surface of the first nanosheet, a second upper metal layer provided on the second upper silicide layer, a second lower metal layer provided on the second lower silicide layer, and a second nanosheet region provided between the second upper silicide layer and the second lower silicide layer.

Each of the plurality of nanosheets may include a single layer continuously extending from the gate electrode to the first source/drain region in the first horizontal direction and continuously extending from the gate electrode to the second source/drain region in a first reverse horizontal direction.

Each of the first source/drain region and the second source/drain region may include non-epitaxial growth layers.

The first upper metal layer may be provided above the first nanosheet, which is an uppermost nanosheet among the plurality of nanosheets, and wherein the first lower metal layer provided on the first nanosheet and a second nanosheet, among the plurality of nanosheets.

The integrated circuit semiconductor device may further include channel regions in the plurality of nanosheets between the plurality of gate electrode portions, and non-channel regions in the plurality of nanosheets between the first upper silicide layer and the first lower silicide layer or between the second upper silicide layer and the second lower silicide layer, the—channel regions being in contact with the first and second source/drain regions.

The integrated circuit semiconductor device may further include a first spacer provided between the gate electrode and the first source/drain region; and a second spacer provided between the gate electrode and the second source/drain region.

The integrated circuit semiconductor device may further include a through-electrode formed in the substrate, the through-electrode being electrically connected to a backside power rail electrically connected to the first and second source/drain regions, and contact electrodes connected to a wiring layer, the contact electrodes being formed in the first and second source/drain regions.

According to another aspect of the disclosure, there is provided a lower nanosheet provided on a substrate, the lower nanosheet extending in a first horizontal direction; an upper nanosheet provided on the substrate, the upper nanosheet extending in the first horizontal direction and being apart from a surface of the substrate in a first vertical direction that is perpendicular to the first horizontal direction; an isolation-insulating layer configured to insulate the lower nanosheet and the upper nanosheet from each other; a gate electrode including a plurality of gate electrode portions provided on the upper and lower nanosheets, the gate electrode extending in a second horizontal direction perpendicular to the first horizontal direction; a first source/drain region provided on a first side of the lower and upper nanosheets corresponding to the gate electrode; and a second source/drain region formed on a second side of the lower and upper nanosheets with corresponding to the gate electrode, wherein the first source/drain region includes: first silicide layers including a first upper silicide layer provided on the lower nanosheet and upper nanosheet and extending inward from an upper surface of the lower nanosheet and upper nanosheet, and a first lower silicide layer on provided the lower nanosheet and upper nanosheet and extending inward from a lower surface of the lower nanosheet and upper nanosheet, a first upper metal layer provided on the first upper silicide layer, a first lower metal layer provided on the first lower silicide layer, and a first nanosheet region provided between the first upper silicide layer and the first lower silicide layer, and wherein the second source/drain region includes: second silicide layers including a second upper silicide layer provided on the lower nanosheet and upper nanosheet and extending inward from the upper surface of the lower nanosheet and upper nanosheet, and a second lower silicide layer provided on the lower nanosheet and upper nanosheet and extending inward from the lower surface of the lower nanosheet and upper nanosheet, a second upper metal layer provided on the second upper silicide layer, a second lower metal layer provided on the second lower silicide layer, and a second nanosheet region provided between the second upper silicide layer and the second lower silicide layer.

Each of the upper nanosheet and the lower nanosheet includes a single layer which continuously extends from the gate electrode to the first source/drain region in the first horizontal direction and extends from the gate electrode to the second source/drain region in a first reverse horizontal direction.

The integrated circuit semiconductor device may further include a first spacer provided between the gate electrode and the first source/drain region; a second spacer provided between the gate electrode and the second source/drain region, wherein the isolation-insulating layer divides the plurality of gate electrode portions in the first vertical direction into first gate electrode portions corresponding to the lower nanosheet and second gate electrode portions corresponding to the upper nanosheet, and wherein the isolation-insulating layer separates the first upper and lower metal layers and the second upper and lower metal layers.

### BRIEF DESCRIPTION OF THE DRAWINGS

The above and/or other aspects will be more clearly understood from the following detailed description taken in conjunction with the accompanying drawings, in which:

FIG. 1 is a layout diagram illustrating an integrated circuit semiconductor device according to an example embodiment;

FIG. 2A is a perspective view illustrating an integrated circuit semiconductor device according to an example embodiment;

FIG. 2B is an enlarged view illustrating some components of the integrated circuit semiconductor device shown in FIG. 2A;

FIG. 3 is a perspective view illustrating an integrated circuit semiconductor device according to an example embodiment;

FIG. 4 is an enlarged view illustrating some components of the integrated circuit semiconductor device shown in FIG. 3;

FIG. 5 is a perspective view illustrating an integrated circuit semiconductor device according to an example embodiment;

FIG. 6 is an enlarged view illustrating some components of the integrated circuit semiconductor device shown in FIG. 5;

FIG. 7 is a perspective view illustrating an integrated circuit semiconductor device according to an example embodiment;

FIG. 8 is an enlarged view illustrating some components of the integrated circuit semiconductor device shown in FIG. 7;

FIG. 9 is a cross-sectional view illustrating an integrated circuit semiconductor device according to an example embodiment;

FIG. 10 is a cross-sectional view illustrating an integrated circuit semiconductor device according to an example embodiment;

FIG. 11 is a cross-sectional view illustrating an integrated circuit semiconductor device according to an example embodiment;

FIG. 12 is a cross-sectional view illustrating an integrated circuit semiconductor device according to an example embodiment;

FIGS. 13 to 18 are cross-sectional views illustrating a method of manufacturing an integrated circuit semiconductor device, according to an example embodiment; and

FIGS. 19 to 24 are cross-sectional views illustrating a method of manufacturing an integrated circuit semiconductor device, according to an example embodiment.

### DETAILED DESCRIPTION

Hereinafter, example embodiments will be described with reference to the accompanying drawings. The following embodiments may be implemented individually or in combination. Therefore, the disclosure should not be construed as being limited to one of the embodiments.

In the disclosure, the terms of a singular form may include plural forms unless otherwise mentioned. In the disclosure, the drawings may be exaggerated to clearly describe the disclosure.

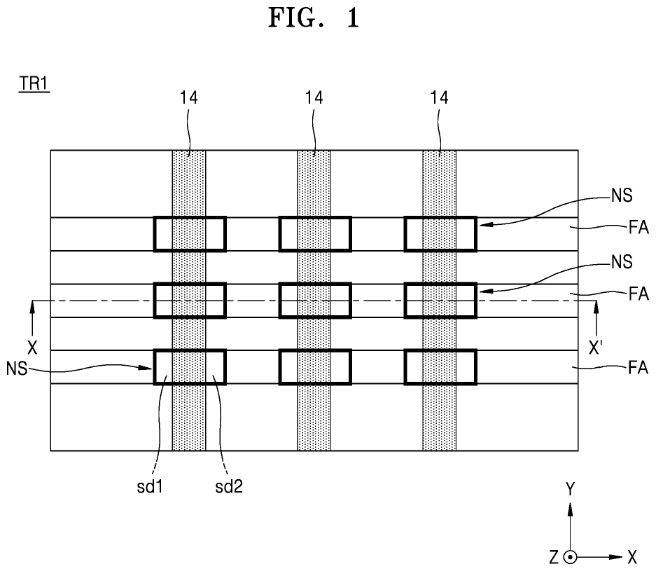

FIG. 1 is a layout diagram illustrating an integrated circuit semiconductor device TR1 according to an example embodiment.

For example, the integrated circuit semiconductor device TR1 may include active regions FA, nanosheets NS, gate electrodes 14, a first source/drain region sd1 and a second source/drain sd2. The active regions FA may extend above a substrate in a first horizontal direction (X direction) and may be spaced apart from each other in a second horizontal direction (Y direction). On the substrate, the second horizontal direction (Y direction) may be perpendicular to the first horizontal direction (X direction).

The nanosheets NS may be provided on the active regions FA. The nanosheets NS may be spaced apart from each other in the first horizontal direction (X direction) and the second horizontal direction (Y direction). The nanosheets NS may include semiconductor layers, for example, silicon layers. The gate electrodes 14 may extend in the second horizontal direction (Y direction) above the active regions FA and may be spaced apart from each other in the first horizontal direction (X direction). The first and second source/drain regions sd1 and sd2 may be arranged on both sides of each of the gate electrodes 14.

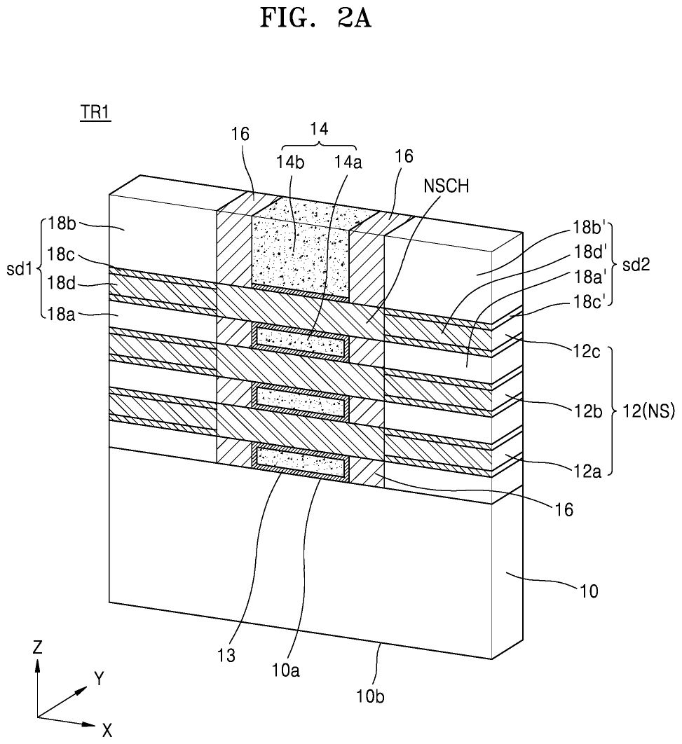

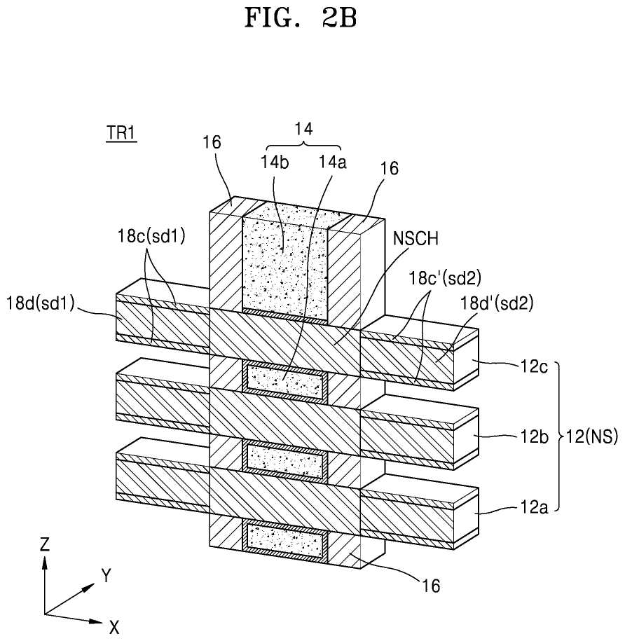

FIG. 2A is a perspective view illustrating an integrated circuit semiconductor device TR1 according to an example embodiment, and FIG. 2B is an enlarged view illustrating some components of the integrated circuit semiconductor device TR1 shown in FIG. 2A.

For example, the integrated circuit semiconductor device TR1 may include a substrate 10, nanosheets 12 (NS), a gate electrode 14, a first source/drain region sd1, and a second source/drain region sd2. The substrate 10 may have a front surface 10a and a back surface (or lower surface) 10b. Here, the front surface 10a may also be referred to an upper surface (or top surface) and the back surface 10b may be referred to a lower surface (or a bottom surface). FIGS. 2A and 2B may be partial views taken along line X-X′ of FIG. 1. In the drawings described below, a first horizontal direction may refer to an X direction parallel to a surface of the substrate 10, and a second horizontal direction may refer to a Y direction perpendicular to the X direction and parallel to the surface of the substrate 10. A first vertical direction may refer to a Z direction that is perpendicular to the surface of the substrate 10 and also perpendicular to the X and Y directions.

According to an example embodiment, the substrate 10 may include a semiconductor such as Si or Ge, or a compound semiconductor such as SiGe, SiC, GaAs, InAs, or InP. According to an example embodiment, the substrate 10 may include at least one selected from the group consisting of a Group III-V material and a Group IV material. According to an example embodiment, the substrate 10 may include a silicon insulator such as SiO₂, SiN, or the like.

The Group III-V material may be a binary, ternary, or quaternary compound containing at least one Group III element and at least one Group V element. The Group III-V material may be a compound including at least one selected from the group consisting of In, Ga, and Al as a Group III element and at least selected from the group consisting of As, P, and Sb as a Group V element.

For example, the Group III-V material may be selected from InP, InzGal-zAs (0≤z≤1), and AlzGal-zAs (0≤z≤1). For example, the binary compound may be any one of InP, GaAs, InAs, InSb, and GaSb. The ternary compound may be any one of InGaP, InGaAs, AlInAs, InGaSb, GaAs Sb, and GaAsP. The Group IV material may be Si or Ge. However, the Group III-V material and the Group IV material, which may be used in integrated circuit semiconductor devices of the disclosure, are not limited to the materials stated above.

Group III-V materials and Group IV materials such as Ge may be used as channel materials for low-power, high-speed transistors. A high-performance complementary metal oxide semiconductor (CMOS) may be formed by using a semiconductor substrate, which includes a Group III-V material such as GaAs and has a higher electron mobility than a Si substrate, and a semiconductor substrate, which includes a semiconductor material such as Ge and has a higher hole mobility than a Si substrate. According to an example embodiment, the substrate 10 may have a silicon-on-insulator (SOI) structure. In the current example embodiment, an example in which a silicon substrate is used as the substrate 10 is described.

According to an example embodiment, the integrated circuit semiconductor device TR1 may include a three-dimensional transistor provided on the substrate 10. Moreover, integrated circuit semiconductor device TR1 may include the nanosheets 12 (NS), the gate electrode 14, the first source/drain region sd1, and the second source/drain region sd2. The integrated circuit semiconductor device TR1 may include a gate-all-around transistor or a contact-all-around transistor. The integrated circuit semiconductor device TR1 may include a multi-bridge-channel field effect transistor (FET).

The nanosheets 12 extend in the first horizontal direction (X direction) above the substrate 10. The nanosheets 12 may be spaced apart from the front surface 10a of the substrate 10. The nanosheets 12 are spaced apart from each other in the first vertical direction (Z direction) above the front surface 10a of the substrate 10. The nanosheets 12 may each be a single layer that is continuous in the first horizontal direction (X direction). The nanosheets 12 may include semiconductor layers such as silicon layers.

The nanosheets 12 may include a first nanosheet 12a, a second nanosheet 12b, and a third nanosheet 12c. According to an example embodiment, the first nanosheet 12a may be provided above the front surface 10a of the substrate 10, the second nanosheet 12b may be provided above the first nanosheet 12a, and the third nanosheet 12c may be provided above the second nanosheet 12b. In the current example embodiment, three nanosheets 12 are provided, but more or fewer nanosheets may be provided. Among the nanosheets 12, the first nanosheet 12a that is the lowermost nanosheet is spaced apart from the front surface 10a of the substrate 10 in the first vertical direction (Z direction). Each of the nanosheets 12 may have a thickness of several nanometers (nm).

The gate electrode 14 may extend in the second horizontal direction (Y direction) perpendicular to the first horizontal direction (X direction) while surrounding the nanosheets 12 with gate insulating layers 13 therebetween. The gate electrode 14 may include lower gate electrodes 14a formed between the nanosheets 12, and an upper gate electrode 14b provided on the third nanosheet (uppermost nanosheet) 12c, which is uppermost among the nanosheets 12. Channel regions NSCH of the nanosheets 12 may be provided on upper and lower portions of the gate electrode 14.

The first source/drain region sd1 may be formed on a first side of the channel regions NSCH in the nanosheets 12 corresponding to the gate electrode 14. The second source/drain region sd2 may be formed on a second side of the channel regions NSCH in the nanosheets 12 corresponding to the gate electrode 14. The second side of the channel regions NSCH in the nanosheets 12 is opposite to the first side of the channel regions NSCH in the nanosheets 12.

Spacers 16 may be formed between the gate electrode 14 and the first and second source/drain regions sd1 and sd2 in the first horizontal direction (X direction). For example, spacers 16 may be formed between the gate electrode 14 and the first source/drain regions sd1 and between the spacers 16 and the second source/drain regions sd2 in the first horizontal direction (X direction). The spacers 16 may be formed by insulating layers such as silicon oxide layers or silicon nitride layers. The nanosheets 12 extend from the gate electrode 14 to the second source/drain region sd2 in the first horizontal direction (X direction) and to the first source/drain region sd1 in a first reverse horizontal direction (—X direction).

The first source/drain region sd1 may include first silicide layers 18c formed inward from front and back surfaces of the nanosheets 12, first metal layers 18a and 18b surrounding the nanosheets 12 from upper and lower sides of the first silicide layers 18c, and first nanosheet regions 18d of the nanosheets 12 that are positioned between the first silicide layers 18c. For example, the first silicide layers 18c may include a top first silicide layer 18c provided on an upper portion of the uppermost nanosheet 12c of the nanosheets 12 and a bottom first silicide layer 18c provided on a lower portion of the uppermost nanosheet 12c of the nanosheets 12. The top first silicide layer 18c may extend inwardly from the upper portion of the uppermost nanosheet 12c of the nanosheets 12 and the bottom first silicide layer 18c may extend inwardly from the lower portion of the uppermost nanosheet 12c of the nanosheets 12. The first silicide layers 18c of the first source/drain region sd1 may be formed in inner regions of the nanosheets 12. The first silicide layers 18c may be metal silicide layers or polycide layers. The first nanosheet regions 18d of the nanosheets 12 that are positioned between the first silicide layers 18c may be regions doped with a dopant such as boron, arsenic, or phosphorus.

According to an example embodiment, the metal silicide layers may include titanium silicide, tungsten silicide, molybdenum silicide, cobalt silicide, or the like. The first metal layers 18a and 18b may include a metal, a conductive metal nitride, or a combination thereof. The first metal layers 18a and 18b may include W, Cu, Al, Ti, Ta, TiN, TaN, MOP, an alloy thereof, or a combination thereof.

The first metal layers 18a and 18b may include first lower metal layers 18a formed between the nanosheets 12, and a first upper metal layer 18b formed on the uppermost nanosheet 12c of the nanosheets 12. The nanosheets 12 that are in contact with the first silicide layers 18c may be non-epitaxial growth layers. The first source/drain region sd1 may include a non-epitaxial growth layer.

The second source/drain region sd2 may include second silicide layers 18c′ formed inward from the front and back surfaces of the nanosheets 12, second metal layers 18a′ and 18b′ surrounding the nanosheets 12 from upper and lower sides of the second silicide layers 18c′, and second nanosheet regions 18d′ of the nanosheets 12 that are positioned between the second silicide layers 18c′. For example, the second silicide layers 18c′ may include a top second silicide layer 18c′ provided on an upper portion of the uppermost nanosheet 12c of the nanosheets 12 and a bottom second silicide layer 18c′ provided on a lower portion of the uppermost nanosheet 12c of the nanosheets 12. The top second silicide layer 18c′ may extend inwardly from the upper portion of the uppermost nanosheet 12c of the nanosheets 12 and the bottom second silicide layer 18c′ may extend inwardly from the lower portion of the uppermost nanosheet 12c of the nanosheets 12. The second silicide layers 18c′ of the second source/drain region sd2 may be formed in inner regions of the nanosheets 12. The second silicide layers 18c′ may be metal silicide layers or polycide layers. The second nanosheet regions 18d′ of the nanosheets 12 that are positioned between the second silicide layers 18c′ may be regions doped with a dopant such as boron, arsenic, or phosphorus.

According to an example embodiment, the metal silicide layers include titanium silicide, tungsten silicide, molybdenum silicide, cobalt silicide, or the like. The second metal layers 18a′ and 18b′ may include a metal, a conductive metal nitride, or a combination thereof. The second metal layers 18a′ and 18b′ may include W, Cu, Al, Ti, Ta, TiN, TaN, MOP, an alloy thereof, or a combination thereof.

The second metal layers 18a′ and 18b′ may include second lower metal layer 18a′ formed between the nanosheets 12, and a second upper metal layer 18b′ positioned on the uppermost nanosheet 12c of the nanosheets 12. The nanosheets 12 that are in contact with the second silicide layers 18c′ may be non-epitaxial growth layers. The second source/drain region sd2 may include a non-epitaxial growth layer.

As described above, in the integrated circuit semiconductor device TR1, the first and second source/drain regions sd1 and sd2 may include non-epitaxial growth layers instead of epitaxial growth layers. Therefore, the contact resistance of the integrated circuit semiconductor device TR1 may be reduced by increasing the surface areas of the first and second source/drain regions sd1 and sd2.

As described above, the integrated circuit semiconductor device TR1 may include a three-dimensional transistor including the source/drain regions sd1 and sd2 having low contact resistance. Therefore, the integrated circuit semiconductor device TR1 of the disclosure may improve electrical characteristics of the three-dimensional transistor such as a short channel effect, and may further improve the current driving capability of the three-dimensional transistor.

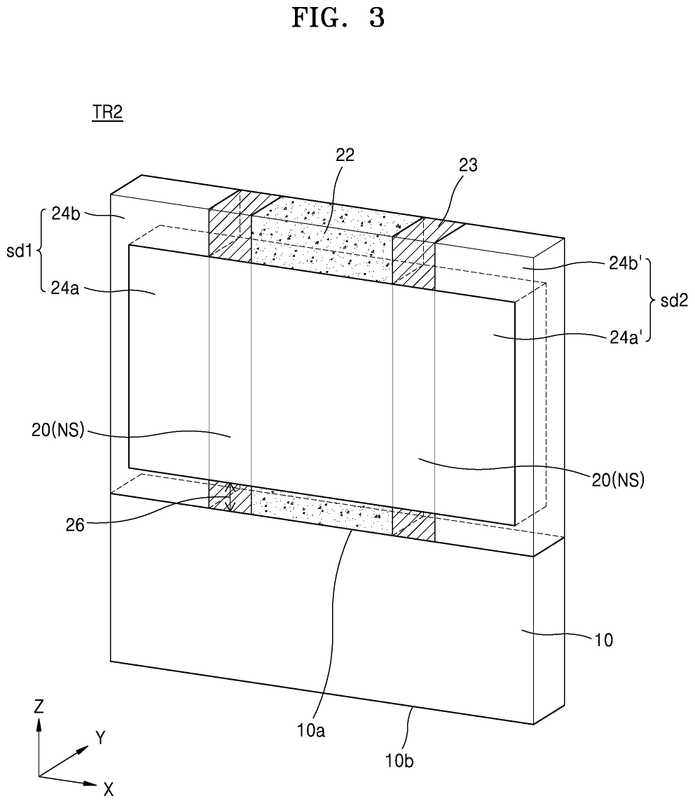

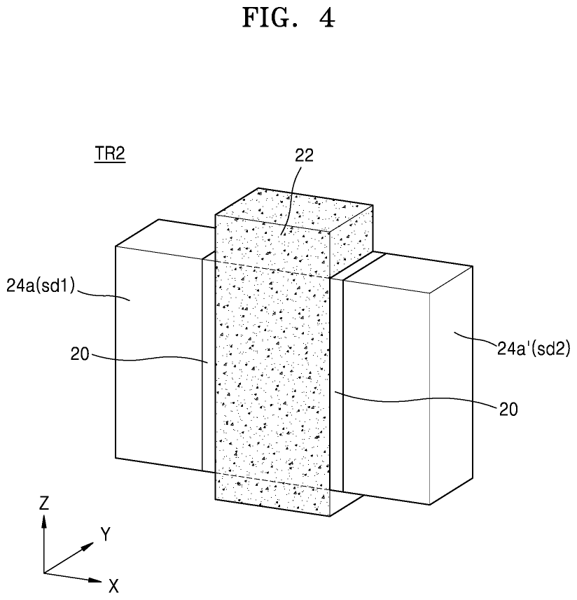

FIG. 3 is a perspective view illustrating an integrated circuit semiconductor device TR2 according to an example embodiment, and FIG. 4 is an enlarged view illustrating some components of the integrated circuit semiconductor device TR2 shown in FIG. 3.

For example, the integrated circuit semiconductor device TR2 may be substantially the same as the integrated circuit semiconductor device TR1 described with reference to FIGS. 1, 2A, and 2B except for the configuration of a nanosheet 20 (NS).

According to an example embodiment, the integrated circuit semiconductor device TR2 may include a substrate 10, the nanosheet 20 (NS), a gate electrode 22, a first source/drain region sd1, and a second source/drain region sd2. The substrate 10 may have a front surface (or upper surface) 10a and a back surface (or lower surface) 10b. The integrated circuit semiconductor device TR2 may include a three-dimensional transistor provided on the substrate 10 and including the nanosheet 20 (NS), the gate electrode 22, the first source/drain region sd1, and the second source/drain region sd2.

The integrated circuit semiconductor device TR2 may include a gate-all-around transistor or a contact-all-around transistor. The integrated circuit semiconductor device TR2 may include a standing nanosheet FET.

The nanosheet 20 extends in the first horizontal direction (X direction) on the substrate 10. The nanosheet 20 may be spaced apart from the front surface 10a of the substrate 10 as indicated by reference numeral 26. The nanosheet 20 may be spaced apart from the front surface 10a of the substrate 10 in the first vertical direction (Z direction). The nanosheet 20 may be a single layer that is continuous in the first horizontal direction (X direction). The nanosheet 20 is formed above the substrate 10, and the thickness of the nanosheet 20 in the first vertical direction (Z direction) is greater than the thickness (or width) of the nanosheet 20 in the second horizontal direction (Y direction). The nanosheet 20 may include a semiconductor layer such as a silicon layer.

Although the integrated circuit semiconductor device TR2 of the current example embodiment is illustrated as having one nanosheet 20, the integrated circuit semiconductor device TR2 may include two or more nanosheets. In this case, the nanosheets may be spaced apart from each other in the first vertical direction (Z direction). The nanosheet 20 may have a thickness of several nanometers (nm).

The gate electrode 22 may extend in the second horizontal direction (Y direction) perpendicular to the first horizontal direction (X direction) while providing a gate insulating layer between the nanosheet 20 and the gate electrode 22. According to an example embodiment, the nanosheet 20 may be surrounded by the gate insulating layer and or the gate electrode 22. Spacers 23 may be formed on both sides of the gate electrode 22. The spacers 23 may be formed by insulating layers such as silicon oxide layers or silicon nitride layers.

The first source/drain regions sd1 may be formed on a side of the nanosheet 20 with respect to the gate electrode 22. The second source/drain region sd2 may be formed on the other side of the nanosheet 20 with respect to the gate electrode 22. The nanosheet 20 extends from the gate electrode 22 to the second source/drain region sd2 and extends from the gate electrode 22 to the first second source/drain region sd1 in the first horizontal direction (X direction) and a first reverse horizontal direction (—X direction).

The first source/drain region sd1 may include a first silicide layer 24a formed inward from a surface of the nanosheet 20, and a first metal layer 24b surrounding the first silicide layer 24a and the nanosheet 20. The first silicide layer 24a may be formed on upper and lower surfaces of the nanosheet 20. The first silicide layer 24a may be a metal silicide layer or a polycide layer.

According to an example embodiment, the metal silicide layer may include titanium silicide, tungsten silicide, molybdenum silicide, cobalt silicide, or the like. The first metal layer 24b may include a metal, a conductive metal nitride, or a combination thereof. The first metal layer 24b may include W, Cu, Al, Ti, Ta, TiN, TaN, MOP, an alloy thereof, or a combination thereof. The nanosheet 20 that is in contact with the first silicide layer 24a may be a non-epitaxial growth layer. The first source/drain region sd1 may include a non-epitaxial growth layer.

The second source/drain region sd2 may include a second silicide layer 24a′ formed inward from a surface of the nanosheet 20, and a second metal layer 24b′ surrounding the second silicide layer 24a′ and the nanosheet 20. The second silicide layer 24a′ may be formed on upper and lower surfaces of the nanosheet 20.

The second silicide layer 24a′ may be a metal silicide layer or a polycide layer. According to an example embodiment, the metal silicide layer may include titanium silicide, tungsten silicide, molybdenum silicide, cobalt silicide, or the like. The second metal layer 24b′ may include a metal, a conductive metal nitride, or a combination thereof. The second metal layer 24b′ may include W, Cu, Al, Ti, Ta, TiN, TaN, MOP, an alloy thereof, or a combination thereof. The nanosheet 20 that is in contact with the second silicide layer 24a′ may be a non-epitaxial growth layer. The second source/drain region sd2 may include a non-epitaxial growth layer.

As described above, in the integrated circuit semiconductor device TR2, the first and second source/drain regions sd1 and sd2 may include non-epitaxial growth layers instead of epitaxial growth layers. Therefore, the contact resistance of the integrated circuit semiconductor device TR2 may be reduced by increasing the surface areas of the first and second source/drain regions sd1 and sd2.

As described above, the integrated circuit semiconductor device TR2 may include a three-dimensional transistor including the source/drain regions sd1 and sd2 having low contact resistance. Therefore, the integrated circuit semiconductor device TR2 of the disclosure may improve electrical characteristics of the three-dimensional transistor such as a short channel effect, and may further improve the current driving capability of the three-dimensional transistor.

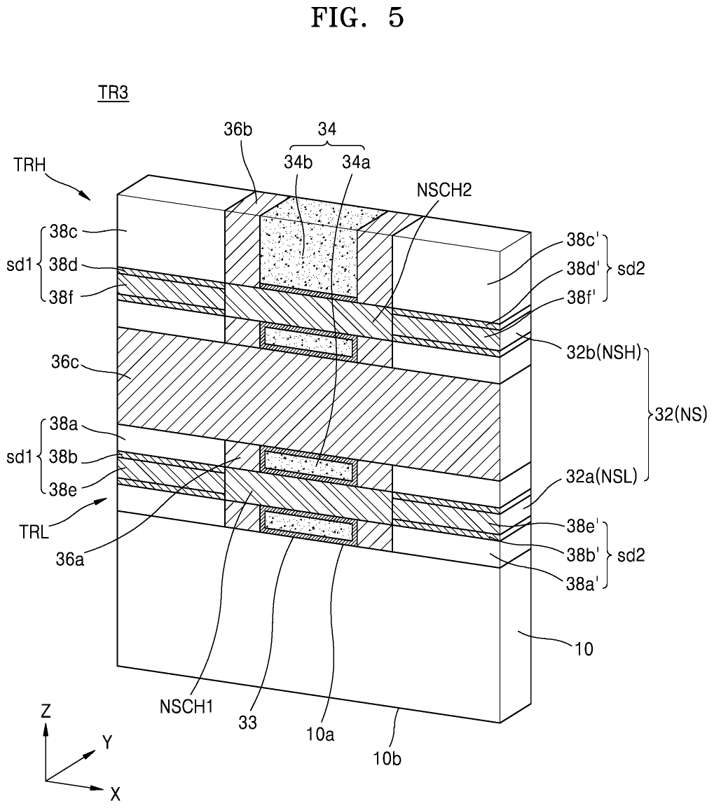

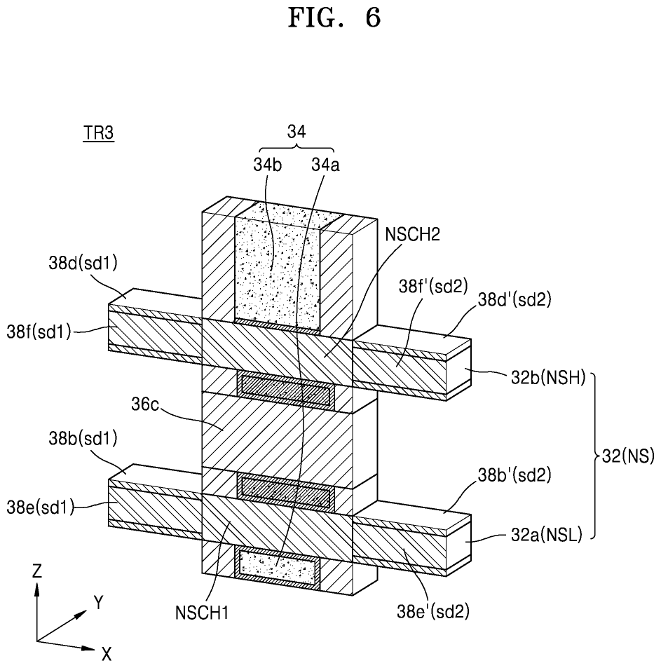

FIG. 5 is a perspective view illustrating an integrated circuit semiconductor device TR3 according to an example embodiment, and FIG. 6 is an enlarged view illustrating some components of the integrated circuit semiconductor device TR3 shown in FIG. 5.

For example, the integrated circuit semiconductor device TR3 may be substantially the same as the integrated circuit semiconductor device TR1 described with reference to FIGS. 1, 2A, and 2B except that the integrated circuit semiconductor device TR3 further includes an isolation-insulating layer 36c between nanosheets 32 (NS).

The integrated circuit semiconductor device TR3 may include a substrate 10, the nanosheets 32 (NS), a gate electrode 34, a first source/drain region sd1, and a second source/drain region sd2. The substrate 10 may have a front surface (or upper surface) 10a and a back surface (or lower surface) 10b. The integrated circuit semiconductor device TR3 may include a three-dimensional transistor provided on the substrate 10 and including the nanosheets 32 (NS), the gate electrode 34, the first source/drain region sd1, and the second source/drain region sd2.

The integrated circuit semiconductor device TR3 may include a gate-all-around transistor or a contact-all-around transistor. The integrated circuit semiconductor device TR3 may include a double-side logic FET.

The nanosheets 32 extend in the first horizontal direction (X direction) above the substrate 10. The nanosheets 32 may be spaced apart from the front surface 10a of the substrate 10. The nanosheets 32 are spaced apart from each other in the first vertical direction (Z direction) above the front surface 10a of the substrate 10. The nanosheets 32 may each be a single layer that is continuous in the first horizontal direction (X direction). The nanosheets 32 may include semiconductor layers such as silicon layers.

The nanosheets 32 may include a lower nanosheet 32a (NSL) extending in the first horizontal direction (X direction) above the substrate 10. The nanosheets 32 may include an upper nanosheet 32b (NSH), which extends above the substrate 10 in the first horizontal direction (X direction) and is spaced apart from the front surface 10a of the substrate 10 in the first vertical direction (Z direction) perpendicular to the first horizontal direction (X direction).

In the current example embodiment, the nanosheets 32 include the lower nanosheet 32a and the upper nanosheet 32b as one set of nanosheets. However, the nanosheets 32 may include more sets of nanosheets. The lower nanosheet 32a is spaced apart from the front surface 10a of the substrate 10 in the first vertical direction (Z direction). Each of the lower nanosheet 32a and the upper nanosheet 32b may have a thickness of several nanometers (nm).

The integrated circuit semiconductor device TR3 may include the isolation-insulating layer 36c insulating the lower nanosheet 32a and the upper nanosheet 32b from each other. The integrated circuit semiconductor device TR3 may include the isolation-insulating layer 36c such that symmetrical three-dimensional transistors may be provided in the first vertical direction (Z direction). The integrated circuit semiconductor device TR3 may include a lower three-dimensional transistor TRL on a lower side of the isolation insulation layer 36c, and an upper three-dimensional transistor TRH on an upper side of the isolation-insulating layer 36c.

The gate electrode 34 may extend in the first horizontal direction (X direction) and the second horizontal direction (Y direction) while surrounding the nanosheets 32, that is, the lower nanosheet 32a and the upper nanosheet 32b, with gate insulating layers 33 therebetween. The gate electrode 34 may include a lower gate electrode 34a surrounding the lower nanosheet 32a and an upper gate electrode 34b surrounding the upper nanosheet 32b. A lower channel region NSCH1 of the lower nanosheet 32a may be provided on upper and lower portions of the lower gate electrode 34a. An upper channel region NSCH2 of the upper nanosheet 32b may be provided on upper and lower portions of the upper gate electrode 34b.

The first source/drain region sd1 may be formed on sides of the nanosheets 32, that is, the lower nanosheet 32a and the upper nanosheet 32b with respect to the gate electrode 34. The second source/drain region sd2 may be formed on the other sides of the nanosheets 32, that is, the lower nanosheet 32a and the upper nanosheet 32b, with respect to the gate electrode 34.

Spacers 36a and 36b may be formed between the gate electrode 34 and the first and second source/drain regions sd1 and sd2 in the first horizontal direction (X direction). The spacers 36a and 36b may be formed by insulating layers such as silicon oxide layers or silicon nitride layers.

The spacers 36a may be formed between the lower gate electrode 34a adjacent to the lower nanosheet 32a and the first and second source/drain regions sd1 and sd2. The spacers 36b may be formed between the upper gate electrode 34b adjacent to the upper nanosheet 32b and the first and second source/drain regions sd1 and sd2. The nanosheets 32 extend from the gate electrode 34 to the first and second source/drain regions sd1 and sd2 in the first horizontal direction (X direction) and a first reverse horizontal direction (—X direction).

The first source/drain region sd1 may include first silicide layers 38b and 38d formed inward from front and back surfaces of the lower and upper nanosheets 32a and 32b, first metal layers 38a and 38c surrounding the lower and upper nanosheets 32a and 32b from upper and lower sides of the first silicide layers 38b and 38d, and first nanosheet regions 38e and 38f of the lower and upper nanosheets 32a and 32b, which are positioned between the first silicide layers 38b and 38d.

The first silicide layers 38b and 38d may be metal silicide layers or polycide layers. According to an example embodiment, the metal silicide layers may include titanium silicide, tungsten silicide, molybdenum silicide, cobalt silicide, or the like. The first metal layers 38a and 38c may include a metal, a conductive metal nitride, or a combination thereof.

The first metal layers 38a and 38c may include W, Cu, Al, Ti, Ta, TiN, TaN, MOP, an alloy thereof, or a combination thereof. The first silicide layers 38b and 38d may include first lower silicide layers 38b formed on surfaces of the lower nanosheet 32a, and first upper silicide layers 38d formed on surfaces of the upper nanosheet 32b. The first nanosheet regions 38e and 38f of the lower and upper nanosheets 32a and 32b, which are positioned between the first silicide layers 38b and 38d, may be regions doped with a dopant such as boron, arsenic, or phosphorus.

The first metal layers 38a and 38c may include first lower metal layers 38a surrounding the first lower silicide layers 38b provided on the lower nanosheet 32a, and first upper metal layer 38c surrounding the first upper silicide layers 38d provided on the upper nanosheet 32b. The lower nanosheet 32a and the upper nanosheet 32b that are respectively in contact with the first lower silicide layers 38b and the first upper silicide layers 38b may be non-epitaxial growth layers. The first source/drain region sd1 may include non-epitaxial growth layers.

The second source/drain region sd2 may include second silicide layers 38b′ and 38d′ formed inward from the front and back surfaces of the lower and upper nanosheets 32a and 32b, second metal layers 38a′ and 38c′ surrounding the lower and upper nanosheets 32a and 32b from upper and lower sides of the second silicide layers 38b′ and 38d′, and second nanosheet regions 38e′ and 38f′ of the lower and upper nanosheets 32a and 32b, which are positioned between the second silicide layers 38b′ and 38d′. The second silicide layers 38b′ and 38d′ may be metal silicide layers or polycide layers.

According to an example embodiment, the metal silicide layers may include titanium silicide, tungsten silicide, molybdenum silicide, cobalt silicide, or the like. The second metal layers 38a′ and 38c′ may include a metal, a conductive metal nitride, or a combination thereof. The second metal layers 38a′ and 38c′ may include W, Cu, Al, Ti, Ta, TiN, TaN, MOP, an alloy thereof, or a combination thereof.

The second silicide layers 38b′ and 38d′ may include second lower silicide layers 38b′ formed on surfaces of the lower nanosheet 32a, and second upper silicide layers 38d′ formed on surfaces of the upper nanosheet 32b. The second nanosheet regions 38e′ and 38f′ of the lower and upper nanosheets 32a and 32b, which are positioned between the second silicide layers 38b′ and 38d′, may be regions doped with a dopant such as boron, arsenic, or phosphorus.

The second metal layers 38a′ and 38c′ may include second lower metal layers 38a′ surrounding the second lower silicide layers 38b′ provided on the lower nanosheet 32a, and second upper metal layers 38c′ surrounding the second upper metal layers 38c′ provided on the upper nanosheet 32b.

The lower nanosheet 32a and the upper nanosheet 32b that are respectively in contact with the second lower silicide layers 38b′ and the second upper silicide layers 38d′ may be non-epitaxial growth layers. The second source/drain region sd2 may include non-epitaxial growth layers.

As described above, in the integrated circuit semiconductor device TR3, the first and second source/drain regions sd1 and sd2 may include non-epitaxial growth layers instead of epitaxial growth layers. Therefore, the contact resistance of the integrated circuit semiconductor device TR3 may be reduced by increasing the surface areas of the first and second source/drain regions sd1 and sd2.

As described above, the integrated circuit semiconductor device TR3 may include three-dimensional transistors including the source/drain regions sd1 and sd2 having low contact resistance. Therefore, the integrated circuit semiconductor device TR3 of the disclosure may improve electrical characteristics of the three-dimensional transistors such as a short channel effect, and may further improve the current driving capability of the three-dimensional transistors.

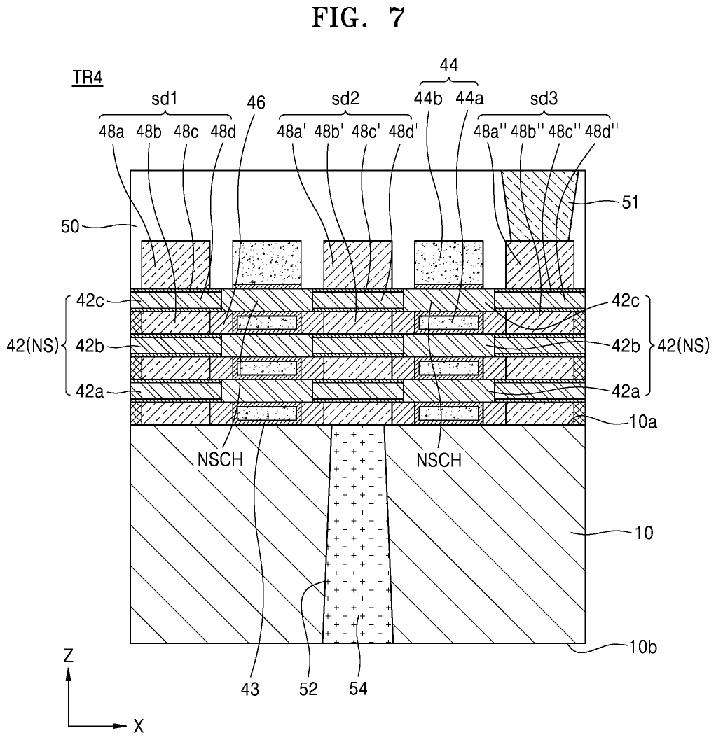

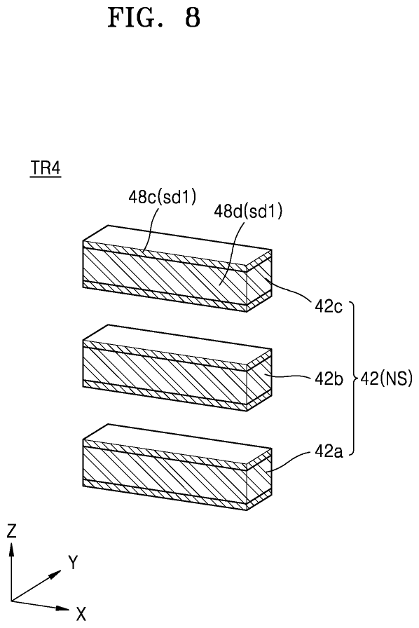

FIG. 7 is a cross-sectional view illustrating an integrated circuit semiconductor device TR4 according to an example embodiment, and FIG. 8 is an enlarged view illustrating some components of the integrated circuit semiconductor device TR4 shown in FIG. 7.

For example, the integrated circuit semiconductor device TR4 may be substantially the same as the integrated circuit semiconductor device TR1 described with reference to FIGS. 1, 2A, and 2B except that a through-electrode 54 and a contact electrode 51 are formed in the integrated circuit semiconductor device TR4.

The integrated circuit semiconductor device TR4 may include a substrate 10, nanosheets 42 (NS), gate electrodes 44, a first source/drain region sd1, a second source/drain region sd2, and a third source/drain region sd3. The substrate 10 may have a front surface (or upper surface) 10a and a back surface (or lower surface) 10b.

The integrated circuit semiconductor device TR4 may include a three-dimensional transistor including the nanosheets 42 (NS), the gate electrodes 44, the first source/drain region sd1, the second source/drain region sd2, and the third source/drain regions sd3.

The nanosheets 42 are spaced apart from each other in the first horizontal direction (X direction) above the substrate 10. The nanosheets 42 may be spaced apart from the front surface 10a of the substrate 10. The nanosheets 42 are spaced apart from each other in the first vertical direction (Z direction) above the front surface 10a of the substrate 10. The nanosheets 42 may each be a single layer that is continuous in the first horizontal direction (X direction). The nanosheets 42 may include semiconductor layers such as silicon layers.

The nanosheets 42 may include a first nanosheet 42a, a second nanosheet 42b, and a third nanosheet 42c. In the current example embodiment, three nanosheets 42 are provided, but more or fewer nanosheets may be provided. The first nanosheet 42a that is the lowermost one of the nanosheets 42 is spaced apart from the front surface 10a of the substrate 10 in the first vertical direction (Z direction). Each of the nanosheets 42 may have a thickness of several nanometers (nm).

The gate electrodes 44 may extend in the second horizontal direction (Y direction) perpendicular to the first horizontal direction (X direction) while surrounding the nanosheets 42 with gate insulating layers 43 therebetween.

Each of the gate electrodes 44 may include lower gate electrodes 44a formed between the nanosheets 42, and an upper gate electrode 44b provided on the third nanosheet 42c that is the uppermost one of the nanosheets 42. Channel regions NSCH of the nanosheets 42 may be provided on upper and lower portions of each of the gate electrodes 44.

The first source/drain region sd1, the second source/drain region sd2, and the third source/drain region sd3 may be formed between the nanosheets 42 in the first horizontal direction (X direction). Spacers 46 may be formed between the gate electrodes 44 and the first to third source/drain regions sd1, sd2, and sd3 in the first horizontal direction (X direction). For example, a first spacer 46 may be formed between the first source/drain region sd1 and a first gate electrode 44, a second spacer 46 may be formed between the first gate electrode 44 and a second source/drain region sd2, and a third spacer 46 may be formed between the second source/drain region sd2 and a second gate electrode 44 and in the first horizontal direction (X direction). The spacers 46 may be formed by insulating layers such as silicon oxide layers or silicon nitride layers.

The first source/drain region sd1 may include first silicide layers 48c formed inward from front and back surfaces of the nanosheets 42, first metal layers 48a and 48b surrounding the nanosheets 42 from upper and lower sides of the first silicide layers 48c, and first nanosheet regions 48d of the nanosheets 42, which are provided between the first silicide layers 48c.

As shown in FIG. 8, the first silicide layers 48c may be formed on upper and lower surfaces of the nanosheets 42. The first silicide layers 48c may be metal silicide layers or polycide layers. The first nanosheet regions 48d of the nanosheets 42 that are provided between the first silicide layers 48c may be regions doped with a dopant such as boron, arsenic, or phosphorus.

According to an example embodiment, the metal silicide layers may include titanium silicide, tungsten silicide, molybdenum silicide, cobalt silicide, or the like. The first metal layers 48a and 48b may include a metal, a conductive metal nitride, or a combination thereof. The first metal layers 48a and 48b may include W, Cu, Al, Ti, Ta, TiN, TaN, MOP, an alloy thereof, or a combination thereof.

The first metal layers 48a and 48b may include first lower metal layers 48b formed between the nanosheets 42, and a first upper metal layer 48a provided on the third nanosheet (uppermost nanosheet) 42c of the nanosheets 42. The nanosheets 42 that are in contact with the first silicide layers 48c may be non-epitaxial growth layers. The first source/drain region sd1 may include non-epitaxial growth layers.

The second source/drain region sd2 may include second silicide layers 48c′ formed inward from the front and back surfaces of the nanosheets 42, second metal layers 48a′ and 48b′ surrounding the nanosheets 42 from upper and lower sides of the second silicide layers 48c′, and second nanosheet regions 48d′ of the nanosheets 42, which are provided between the second silicide layers 48c′.

The second silicide layers 48c′ may be formed on upper and lower surfaces of the nanosheets 42 in the same manner as that shown in FIG. 8. The second silicide layers 48c′ may be metal silicide layers or polycide layers. The second nanosheet regions 48d′ of the nanosheets 42 that are provided between the second silicide layers 48c′ may be regions doped with a dopant such as boron, arsenic, or phosphorus.

According to an example embodiment, the metal silicide layers may be titanium silicide, tungsten silicide, molybdenum silicide, cobalt silicide, or the like. The second metal layers 48a′ and 48b′ may include a metal, a conductive metal nitride, or a combination thereof. The second metal layers 48a′ and 48b′ may include W, Cu, Al, Ti, Ta, TiN, TaN, MOP, an alloy thereof, or a combination thereof.

The second metal layers 48a′ and 48b′ may include second lower metal layer 48b′ formed between the nanosheets 42, and a second upper metal layer 48a′ provided on the uppermost nanosheet 42c of the nanosheets 42. The nanosheets 42 that are in contact with the second silicide layers 48c′ may be non-epitaxial growth layers. The second source/drain region sd2 may include non-epitaxial growth layers.

The third source/drain region sd3 may include third silicide layers 48c″ formed inward from the front and back surfaces of the nanosheets 42, third metal layers 48a″ and 48b″ surrounding the nanosheets 42 from upper and lower sides of the third silicide layers 48c″, and third nanosheet regions 48d″ of the nanosheets 42, which are provided between the third silicide layers 48c″.

The third silicide layers 48c″ may be formed on the upper and lower surfaces of the nanosheets 42 in the same manner as that shown in FIG. 8. The third silicide layers 48c″ may be metal silicide layers or polycide layers. The third nanosheet regions 48d″ of the nanosheets 42 that are provided between the third silicide layers 48c″ may be regions doped with a dopant such as boron, arsenic, or phosphorus.

The third metal layers 48a″ and 48b″ may include third lower metal layers 48b″ formed between the nanosheets 42, and a third upper metal layer 48a″ provided on the uppermost nanosheet 42c of the nanosheets 42. The nanosheets 42 that are in contact with the third silicide layers 48c″ may be non-epitaxial growth layers. The third source/drain region sd3 may include non-epitaxial growth layers.

An interlayer insulating layer 50 is formed on the gate electrodes 44 and the first to third source/drain regions sd1, sd2, and sd3. The contact electrode 51 is formed in the interlayer insulating layer 50 and is electrically connected to the third source/drain region sd3. The through-electrode 54 is formed in the substrate 10. The through-electrode 54 may be a through-silicon-via. The through-electrode 54 may be a conductive layer formed in a through-hole 52, which penetrates the substrate 10 from the front surface 10a to the back surface 10b of the substrate 10.

As described above, the first to third source/drain regions sd1, sd2, and sd3 of the integrated circuit semiconductor device TR4 may include non-epitaxial growth layers instead of epitaxial growth layers. Therefore, the contact resistance of the integrated circuit semiconductor device TR4 may be reduced by increasing the surface areas of the first to third source/drain regions sd1, sd2, and sd3.

For example, in the integrated circuit semiconductor device TR4, the contact resistance between the contact electrode 51 and the third source/drain region sd3 may be reduced by increasing the surface area of the third source/drain region sd3. In addition, because the through-electrode 54 is formed in the substrate 10 of the integrated circuit semiconductor device TR4, a backside power rail may be easily formed.

According to another example embodiment, unlike structure shown in FIG. 7, the substrate 10 may be removed, and a lower insulating layer may be formed under the nanosheets 42. Then, a through-electrode may be formed in the lower insulating layer to easily form a backside power rail.

The integrated circuit semiconductor device TR4 may include a three-dimensional transistor including the first to third source/drain regions sd1, sd2, and sd3 having low contact resistance. Therefore, the integrated circuit semiconductor device TR4 of the disclosure may improve electrical characteristics of the three-dimensional transistors such as a short channel effect and current driving capability.

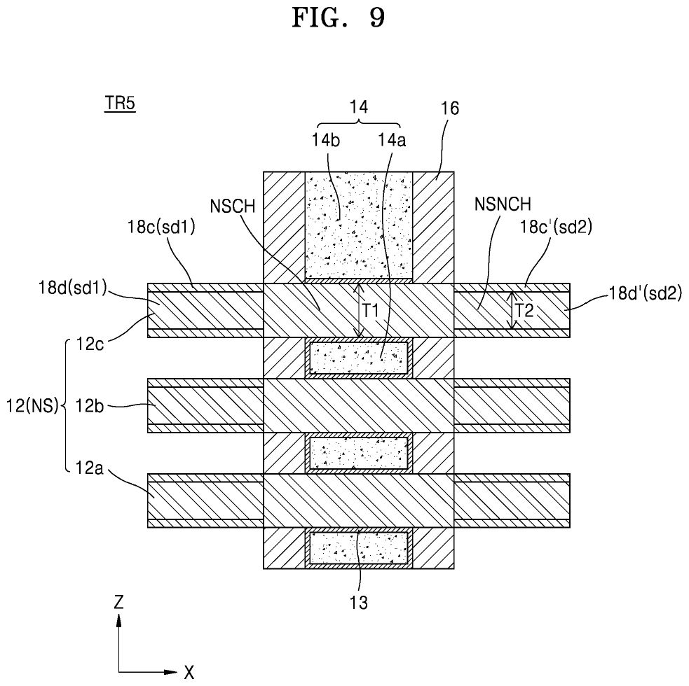

FIG. 9 is a cross-sectional view illustrating an integrated circuit semiconductor device TR5 according to an example embodiment.

For example, the integrated circuit semiconductor device TR5 may be substantially the same as the integrated circuit semiconductor device TR1 described with reference to FIGS. 1, 2A, and 2B except that channel regions NSCH and non-channel regions NSNCH are further marked. The non-channel regions NSNCH may include first and second source/drain regions sd1 and sd2.

The integrated circuit semiconductor device TR5 is for illustrating the thickness between a channel region NSCH and a non-channel region NSNCH of the integrated circuit semiconductor device TR1 shown in FIGS. 1, 2A and 2B. Among the components shown in FIG. 9, the same components as those shown in FIGS. 1, 2A and 2B will be simply described or will not be described.

The integrated circuit semiconductor device TR5 may include nanosheets 12 (NS), a gate electrode 14, the first source/drain region sd1, and the second source/drain region sd2. The nanosheets 12 are spaced apart from each other in the first vertical direction (Z direction). The nanosheets 12 may include a first nanosheet 12a, a second nanosheet 12b, and a third nanosheet 12c. The gate electrode 14 may surround the nanosheets 12 with gate insulating layers 13 therebetween.

The first source/drain region sd1 may include first silicide layers 18c formed inward from front (or upper) and back (or lower) surfaces of the nanosheets 12, and first nanosheet regions 18d of the nanosheets 12, which are provided between the first silicide layers 18c. The first silicide layers 18c may be formed by consuming the front and back surfaces of the nanosheets 12. The first nanosheet regions 18d of the nanosheets 12 that are provided between the first silicide layers 18c may be regions doped with a dopant such as boron, arsenic, or phosphorus.

The second source/drain region sd2 may include second silicide layers 18c′ formed inward from the front (or upper) and back (or lower) surfaces of the nanosheets 12, and second nanosheet regions 18d′ of the nanosheets 12, which are provided between the second silicide layers 18c′. The second silicide layers 18c′ may be formed by consuming the front and back surfaces of the nanosheets 12. The second nanosheet regions 18d′ of the nanosheets 12 that are provided between the second silicide layers 18c′ may be regions doped with a dopant such as boron, arsenic, or phosphorus. Spacers 16 may be formed between the gate electrode 14 and the first and second source/drain regions sd1 and sd2 in the first horizontal direction (X direction).

The nanosheets 12 provided on upper and lower portions of the gate electrode 14 may include the channel regions NSCH. The channel regions NSCH may be formed between the first source/drain region sd1 and the second source/drain region sd2 in the first horizontal direction (X direction). The non-channel regions NSNCH may be formed on upper and lower portions of the first and second silicide layers 18c and 18c′. As described above, the non-channel regions NSNCH may be the first and second source/drain regions sd1 and sd2.

In the first vertical direction (Z direction), a first thickness T1 of each of the channel regions NSCH may be greater than a second thickness T2 of each of the non-channel regions NSNCH. Due to the first and second silicide layers 18c and 18c′, the first thickness T1 of the nanosheets 12, which is measured in a region surrounded by the gate electrode 24, may be greater than the second thickness T2 of the nanosheets 12, which is measured in a region provided on upper and lower portions of the first and second silicide layers 18c and 18c′.

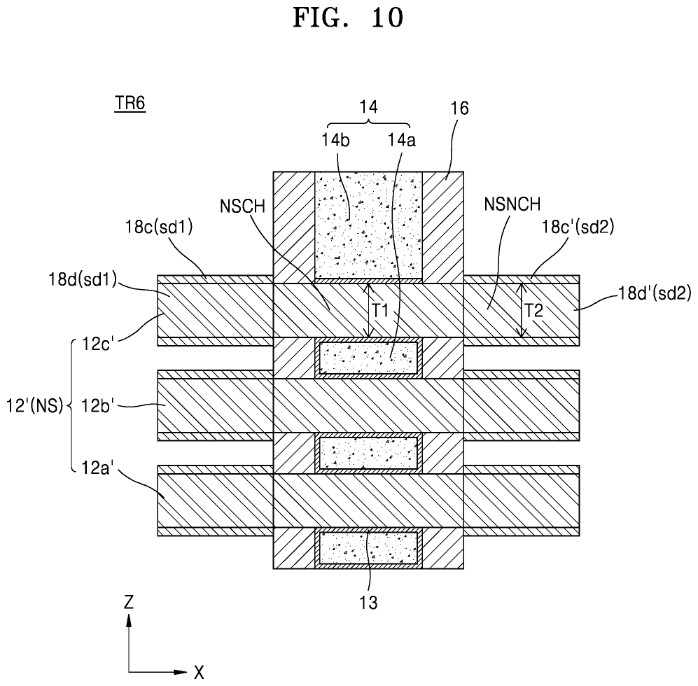

FIG. 10 is a cross-sectional view illustrating an integrated circuit semiconductor device TR6 according to an example embodiment.

For example, the integrated circuit semiconductor device TR6 may be substantially the same as the integrated circuit semiconductor device TR5 described with reference to FIG. 9 except that the thickness of channel regions NSCH is equal to or less than the thickness of non-channel regions NSNCH. The non-channel regions NSNCH may include first and second source/drain regions sd1 and sd2. Among the components shown in FIG. 10, the same components as those shown in FIG. 9 will be simply described or will not be described.

The integrated circuit semiconductor device TR6 may include nanosheets 12′ (NS), a gate electrode 14, the first source/drain region sd1, and the second source/drain region sd2. The nanosheets 12′ are spaced apart from each other in the first vertical direction (Z direction). The nanosheets 12′ may include a first nanosheet 12a′, a second nanosheet 12b′, and a third nanosheet 12c′. The gate electrode 14 may surround the nanosheets 12 with gate insulating layers 13 therebetween.

The first source/drain region sd1 may include first silicide layers 18c formed on front (or upper) and back (or lower) surfaces of the nanosheets 12′, and first nanosheet regions 18d of the nanosheets 12′, which are provided between the first silicide layers 18c. The first silicide layers 18c may be formed on the front and back surfaces of the nanosheet 12′. The first nanosheet regions 18d of the nanosheets 12′ that are provided between the first silicide layers 18c may be regions doped with a dopant such as boron, arsenic, or phosphorus.

The second source/drain region sd2 may include second silicide layers 18c′ formed on the front (or upper) and back (or lower) surfaces of the nanosheet 12′, and second nanosheet regions 18d′ of the nanosheets 12′, which are provided between the second silicide layers 18c′. The second silicide layers 18c′ may be formed on the front and back surfaces of the nanosheets 12. The first and second silicide layers 18c and 18c′ may be formed on the upper and lower surfaces of the nanosheets 12′.

The second nanosheet regions 18d′ of the nanosheets 12′ that are provided between the second silicide layers 18c′ may be regions doped with a dopant such as boron, arsenic, or phosphorus. Spacers 16 may be formed between the gate electrode 14 and the first and second source/drain regions sd1 and sd2 in the first horizontal direction (X direction).

The nanosheets 12′ provided on upper and lower portions of the gate electrode 14 may include the channel regions NSCH. The channel regions NSCH may be formed between the first source/drain region sd1 and the second source/drain region sd2 in the first horizontal direction (X direction). The non-channel regions NSNCH may be formed on upper and lower portions of the first and second silicide layers 18c and 18c′. As described above, the non-channel regions NSNCH may be the first and second source/drain regions sd1 and sd2.

In the first vertical direction (Z direction), a first thickness T1 of each of the channel regions NSCH may be equal to or less than a second thickness T2 of each of the non-channel regions NSNCH. The first thickness T1 of the nanosheets 12′, which is measured in a region surrounded by the gate electrode 24, may be equal to or less than the second thickness T2 of the nanosheets 12, which is measured in a region between the upper and lower portions of the first and second silicide layers 18c and 18c′.

FIG. 10 illustrates that the first thickness T1 of the channel regions NSCH is equal to the second thickness T2 of the non-channel regions NSNCH. However, when the thickness of the nanosheets 12 is increased in the non-channel regions NSNCH, the first thickness T1 of the channel regions NSCH may be less than the second thickness T2 of the non-channel regions NSNCH.

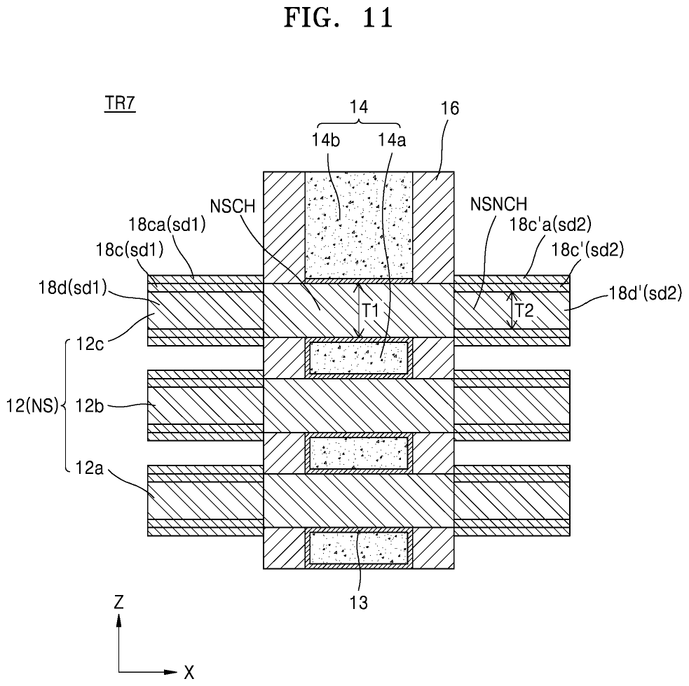

FIG. 11 is a cross-sectional view illustrating an integrated circuit semiconductor device TR7 according to an example embodiment.

For example, the integrated circuit semiconductor device TR7 may be substantially the same as the integrated circuit semiconductor device TR5 described with reference to FIG. 9 except that metal liner layers 18ca and 18c′ a are further formed on upper and lower surfaces of first and second silicide layers 18c and 18c′. Among the components shown in FIG. 11, the same components as those shown in FIG. 9 will be simply described or will not be described.

The integrated circuit semiconductor device TR7 may include nanosheets 12 (NS), a gate electrode 14, a first source/drain region sd1, and a second source/drain region sd2. The nanosheets 12 are spaced apart from each other in the first vertical direction (Z direction). The gate electrode 14 may surround the nanosheets 12 with gate insulating layers 13 therebetween.

The first source/drain region sd1 may include first silicide layers 18c formed

inward from front (or upper) and back (or lower) surfaces of the nanosheet 12, and first nanosheet regions 18d of the nanosheets 12, which are provided between the first silicide layers 18c. The first silicide layers 18c may be formed on the front and back surfaces of the nanosheets 12. The first source/drain region sd1 may include the first metal liner layers 18ca formed on front and back surfaces of the first silicide layers 18c. The first nanosheet regions 18d of the nanosheets 12 that are provided between the first silicide layers 18c may be regions doped with a dopant such as boron, arsenic, or phosphorus.

The first metal liner layers 18ca may include a metal, a conductive metal nitride, or a combination thereof. The first metal liner layers 18ca may include W, Cu, Al, Ti, Ta, TiN, TaN, MOP, an alloy thereof, or a combination thereof.

The second source/drain region sd2 may include second silicide layers 18c′ formed inward from the front (or upper) and back (or lower) surfaces of the nanosheets 12, and second nanosheet regions 18d′ of the nanosheets 12, which are provided between the second silicide layers 18c′. The second silicide layers 18c′ may be formed on the front and back surfaces of the nanosheets 12. The second nanosheet regions 18d′ of the nanosheets 12 that are provided between the second silicide layers 18c′ may be regions doped with a dopant such as boron, arsenic, or phosphorus. The second source/drain region sd2 may include the second metal liner layers 18c′ a formed on front and back surfaces of the second silicide layers 18c′.

The second metal liner layers 18c′ a may include a metal, a conductive metal nitride, or a combination thereof. The second metal liner layer 18c′ a may include W, Cu, Al, Ti, Ta, TiN, TaN, MOP, an alloy thereof, or a combination thereof. Spacers 16 may be formed between the gate electrode 14 and the first and second source/drain regions sd1 and sd2 in the first horizontal direction (X direction).

The nanosheets 12 provided on upper and lower portions of the gate electrode 14 may include channel regions NSCH. The channel regions NSCH may be formed between the first source/drain region sd1 and the second source/drain region sd2 in the first horizontal direction (X direction). Non-channel regions NSNCH may be formed on upper and lower portions of the first and second silicide layers 18c and 18c′. As described above, the non-channel regions NSNCH may be the first and second source/drain regions sd1 and sd2. In the first vertical direction (Z direction), a first thickness T1 of each of the channel regions NSCH may be greater than a second thickness T2 of each of the non-channel regions NSNCH.

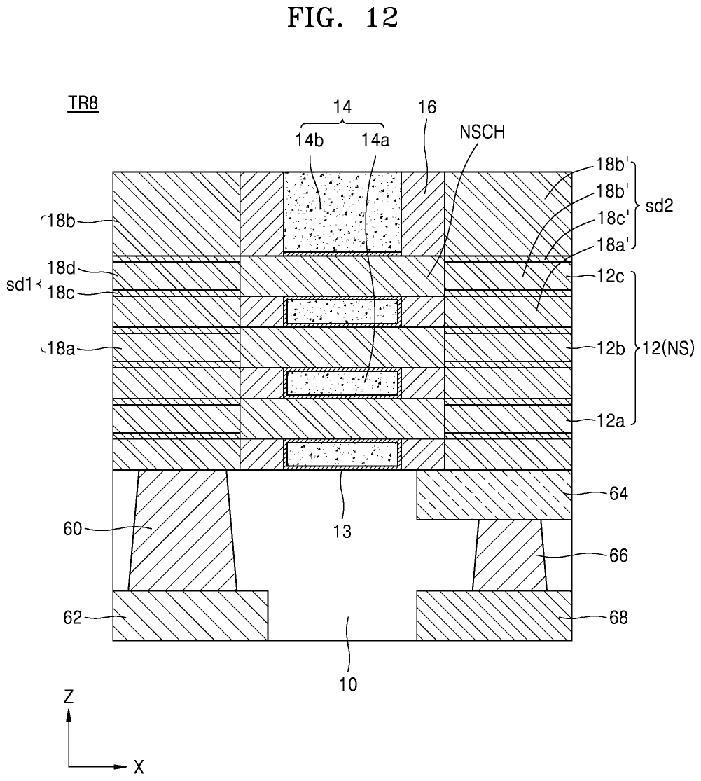

FIG. 12 is a cross-sectional view illustrating an integrated circuit semiconductor device TR8 according to an example embodiment.

For example, the integrated circuit semiconductor device TR8 may be substantially the same as the integrated circuit semiconductor device TR1 described with reference to FIGS. 1, 2A, and 2B except that the integrated circuit semiconductor device TR8 further includes first and second through-electrodes 60 and 66 and first to third backside power rails 62, 64, and 68. Among the components shown in FIG. 12, the same components as those shown in FIGS. 1, 2A, and 2B will be simply described or will not be described.

The integrated circuit semiconductor device TR8 may include nanosheets 12 (NS), a gate electrode 14, a first source/drain region sd1, and a second source/drain region sd2. The nanosheets 12 may include a first nanosheet 12a, a second nanosheet 12b, and a third nanosheet 12c. The gate electrode 14 may surround the nanosheets 12 with gate insulating layers 13 therebetween. The gate electrode 14 may include lower gate electrodes 14a and an upper gate electrode 14b. Channel regions NSCH of the nanosheets 12 may be provided on upper and lower portions of the gate electrode 14.

The first source/drain region sd1 and the second source/drain region sd2 may be formed on a side and the other side of each of the nanosheets 12 with the gate electrode 14 being centered therebetween. Spacers 16 may be formed between the gate electrode 14 and the first and second source/drain regions sd1 and sd2 in the first horizontal direction (X direction).

The first source/drain region sd1 may include first silicide layers 18c, first metal layers 18a and 18b, and first nanosheet regions 18d of the nanosheets 12, which are provided between the first silicide layers 18c. The first metal layers 18a and 18b may include first lower metal layers 18a and a first upper metal layer 18b. The first nanosheet regions 18d of the nanosheets 12 that are provided between the first silicide layers 18c may be regions doped with a dopant such as boron, arsenic, or phosphorus.

The second source/drain region sd2 may include second silicide layers 18c′, second metal layers 18a′ and 18b′, and second nanosheet regions 18d′ of the nanosheets 12, which are provided between the second silicide layers 18c′. The second metal layers 18a′ and 18b′ may include second lower metal layers 18a′ and a second upper metal layer 18b′. The second nanosheet regions 18d′ of the nanosheets 12 that are provided between the second silicide layers 18c′ may be regions doped with a dopant such as boron, arsenic, or phosphorus.

In the integrated circuit semiconductor device TR8, the first through-electrode 60 electrically connected to the first source/drain regions sd1 may be formed in a substrate 10. The first backside power rail 62 electrically connected to the first through-electrode 60 may be formed in a back surface of the substrate 10.

In the integrated circuit semiconductor device TR8, the second backside power rail 64 electrically connected to the second source/drain regions sd2 may be formed in the substrate 10. The second through-electrode 66 may be formed in the second backside power rail 64. The third back side power rail 68 electrically connected to the second through-electrode 66 may be formed in the back surface of the substrate 10. As described above, the integrated circuit semiconductor device TR8 includes through-electrodes and backside power rails formed in the substrate 10, and thus operating voltages may be easily applied to the integrated circuit semiconductor device TR8.

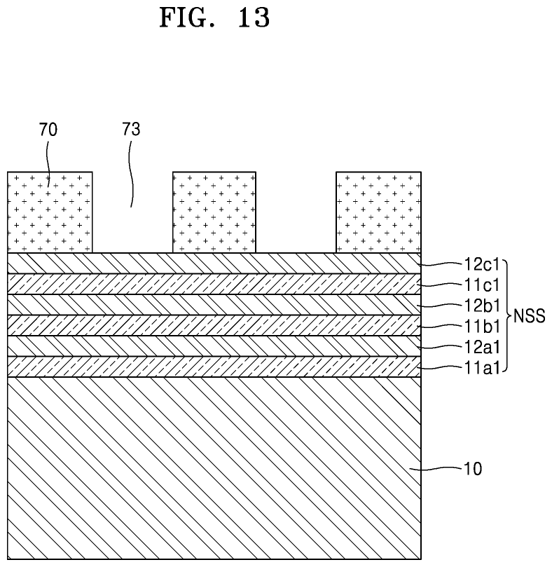

FIGS. 13 to 18 are cross-sectional views illustrating a method of manufacturing an integrated circuit semiconductor device, according to an example embodiment.

For example, FIGS. 13 to 18 illustrate a method of manufacturing the integrated circuit semiconductor device TR1 described with reference to FIGS. 1, 2A and 2B. Among the components shown in FIGS. 13 to 18, the same components as those shown in FIGS. 1, 2A, and 2B will be simply described and, and thus may not be described in detail.

Referring to FIG. 13, a first sacrificial semiconductor layer 11a1, a first nanosheet semiconductor layer 12a1, a second sacrificial semiconductor layer 11b1, a second nanosheet semiconductor layer 12b1, a third sacrificial semiconductor layer 11c1, and a third nanosheet semiconductor layer 12c1 are provided on a substrate 10 to form a nanosheet stack structure NSS. According to an example embodiment, the first sacrificial semiconductor layer 11a1, the first nanosheet semiconductor layer 12a1, the second sacrificial semiconductor layer 11b1, the second nanosheet semiconductor layer 12b1, the third sacrificial semiconductor layer 11c1, and the third nanosheet semiconductor layer 12c1 are sequentially stacked on the substrate 10 to form the nanosheet stack structure NSS.

The nanosheet stack structure NSS may be formed by alternately stacking the first to third sacrificial semiconductor layers 11a1, 11b1, and 11c1 and the first to third nanosheet semiconductor layers 12a1, 12b1, and 12c1. In the current example embodiment, the nanosheet stack structure NSS includes three sacrificial semiconductor layers 11a1, 11b1, and 11cl, and three nanosheet semiconductor layers 12a1, 12b1, and 12c1. However, the disclosure is not limited thereto.

The first to third sacrificial semiconductor layers 11a1, 11b1, and 11cl, and the first to third nanosheet semiconductor layers 12a1, 12b1, and 12c1 may be formed by an epitaxial growth method. The first to third sacrificial semiconductor layers 11a1, 11b1, and 11cl, and the first to third nanosheet semiconductor layers 12a1, 12b1, and 12c1 may include different semiconductor materials.

According to an example embodiment, the first to third sacrificial semiconductor layers 11a1, 11b1, and 11cl may include SiGe, and the first to third nanosheet semiconductor layers 12a1, 12b1, and 12c1 may include Si. However, embodiments are not limited thereto. The first to third sacrificial semiconductor layers 11a1, 11b1, and 11c1 may include a material that is more easily etched than the first to third nanosheet semiconductor layers 12a1, 12b1, and 12c1. The first to third sacrificial semiconductor layers 11a1, 11b1, and 11cl, and the first to third nanosheet semiconductor layers 12a1, 12b1, and 12c1 may all have the same thickness, but the disclosure is not limited thereto.

According to an example embodiment, mask patterns 70 may be formed on the nanosheet stack structure NSS, and the mask patters 70 may be spaced apart from each. First openings 73 may be formed between the mask patterns 70. The mask patterns 70 may include a hard mask pattern. The mask patterns 70 may include silicon nitride, polysilicon, a spin-on hardmask (SOH) material, or a combination thereof, but are not limited thereto.

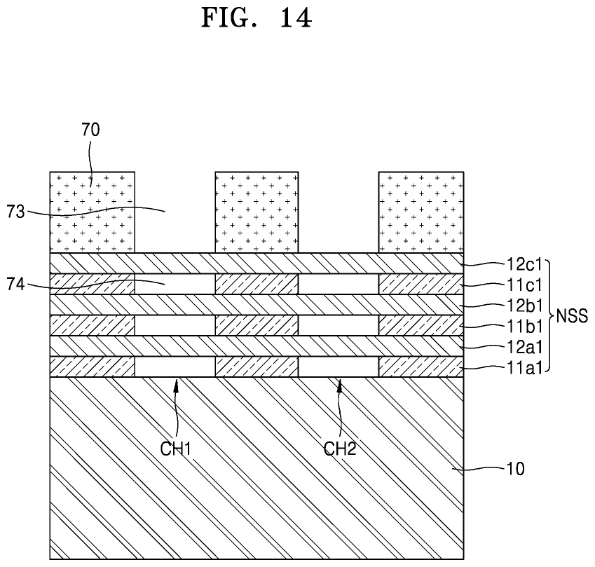

Referring to FIG. 14, the first to third sacrificial semiconductor layers 11a1, 11b1, and 11cl are selectively etched using the mask patterns 70 as etch masks. In this case, the first to third sacrificial semiconductor layers 11a1, 11b1, and 11c1 that are positioned below the first openings 73 are etched, thereby forming second openings 74 between the first to third nanosheet semiconductor layers 12a1, 12b1, and 12c1. The second openings 74 may be formed using a wet etching process.

The wet etching process may be performed using the etching selectivity of the first to third nanosheet semiconductor layers 12a1, 12b1, and 12c1, and the etching selectivity of the first to third sacrificial semiconductor layers 11a1, 11b1, and 11c1. The wet etching process may be performed using an etchant that etches the first to third sacrificial semiconductor layers 11a1, 11b1, and 11c1 faster than the first to third nanosheet semiconductor layers 12a1, 12b1, and 12c1. As such, at least a portion of the first to third nanosheet semiconductor layers 12a1, 12b1, and 12c1 may remain and second openings 74 in the first to third sacrificial semiconductor layers 11a1, 11b1, and 11c1 may be formed.

The first openings 73 and the second openings 74 may include a first region opening group CH1 formed in a first region and a second region opening group CH2 formed in a second area. In a subsequent process, a first source/drain region may be formed in the first region opening group CH1, and a second source/drain region may be formed in the second region opening group CH2.

Subsequently, a dopant such as boron, arsenic, or phosphorus may be ion-implanted into the first to third nanosheet semiconductor layers 12a1, 12b1, and 12c1 exposed through the first openings 73 and the second openings 74. The dopant is implanted into the first to third nanosheet semiconductor layers 12a1, 12b1, and 12c1 exposed through the first region opening group CH1 and the second region opening group CH2. The contact resistance of the first and second source/drain regions may be reduced by implanting the dopant into the first to third nanosheet semiconductor layers 12a1, 12b1, and 12c1.

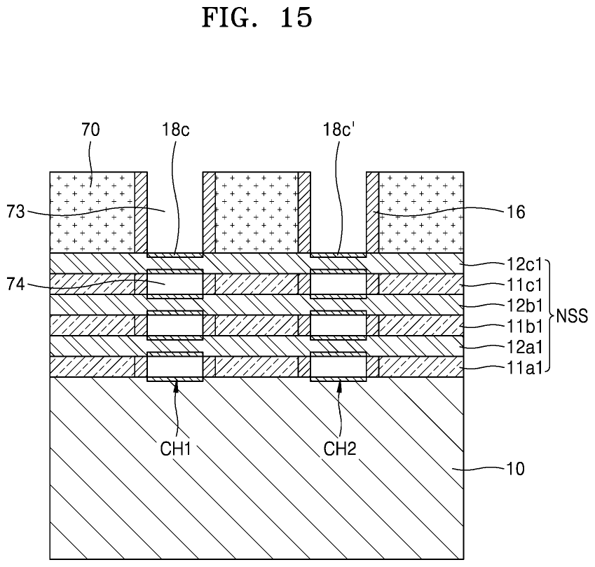

Referring to FIG. 15, spacers 16 are formed on inner sidewalls of the first openings 73 and the second openings 74. The spacers 16 may be formed by insulating layers such as silicon oxide layers or silicon nitride layers. First and second silicide layers 18c and 18c′ are formed on surfaces of the first to third nanosheet semiconductor layers 12a1, 12b1, and 12c1 exposed through the first openings 73 and the second openings 74. The first silicide layers 18c may be formed in the first region opening group CH1, and the second silicide layers 18c′ may be formed in the second region opening group CH2.

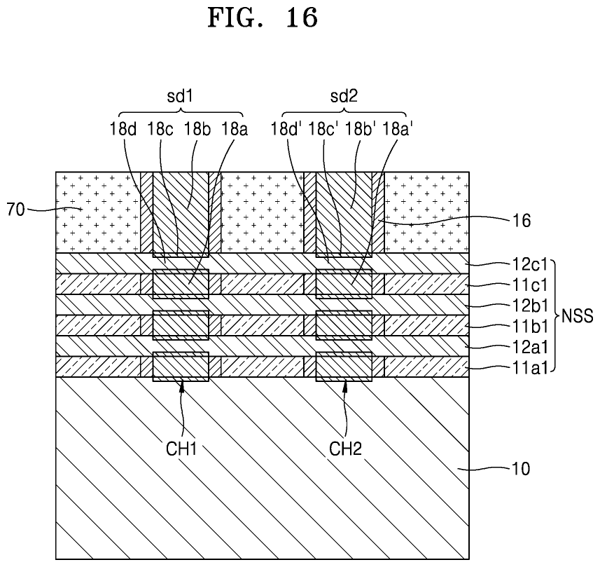

Referring to FIG. 16, first metal layers 18a and 18b and second metal layers 18a′ and 18b′ are formed inside the first openings 73 and the second openings 74. The first metal layers 18a and 18b and the second metal layers 18a′ and 18b′ may be formed on the spacers 16 and the first and second silicide layers 18c and 18c′.

The first metal layers 18a and 18b may be formed in the first region opening group CH1. The first metal layers 18a and 18b may include first lower metal layers 18a formed between the first to third nanosheet semiconductor layers 12a1, 12b1, and 12c1, and a first upper metal layer 18b positioned on the third nanosheet semiconductor layer 12c1 that is the uppermost nanosheet semiconductor layer among the first to third nanosheet semiconductor layers 12a1, 12b1, and 12c1.

The first lower metal layers 18a may be formed in the second openings 74 of the first region opening group CH1, and the first upper metal layer 18b may be formed in the first opening 73 of the first region opening group CH1. Accordingly, a first source/drain region sd1 may be formed to include the first silicide layers 18c, the first metal layers 18a and 18b, and first nanosheet region 18d positioned between the first silicide layers 18c. The first nanosheet regions 18d positioned between the first silicide layers 18c may be regions doped with the dopant such as boron, arsenic, or phosphorus.

The second metal layers 18a′ and 18b′ may be formed in the second region opening group CH2. The second metal layers 18a′ and 18b′ may include second lower metal layers 18a′ formed between the first to third nanosheet semiconductor layers 12a1, 12b1, and 12c1, and a second upper metal layer 18b′ positioned on the third nanosheet semiconductor layer 12c1 that is the uppermost nanosheet semiconductor layer among the first to third nanosheet semiconductor layers 12a1, 12b1, and 12c1. The second lower metal layers 18a′ may be formed in the second openings 74 of the second region opening group CH2, and the second upper metal layer 18b′ may be formed in the first opening 73 of the second region opening group CH2. This process may be formed to form a second source/drain region sd2 including the second nanosheet regions 18d′ provided between the second silicide layers 18c′, the second metal layers 18a′ and 18b′, and the second silicide layers 18c′. The second nanosheet regions 18d′ positioned between the second silicide layers 18c′ may be regions doped with the dopant such as boron, arsenic, or phosphorus.

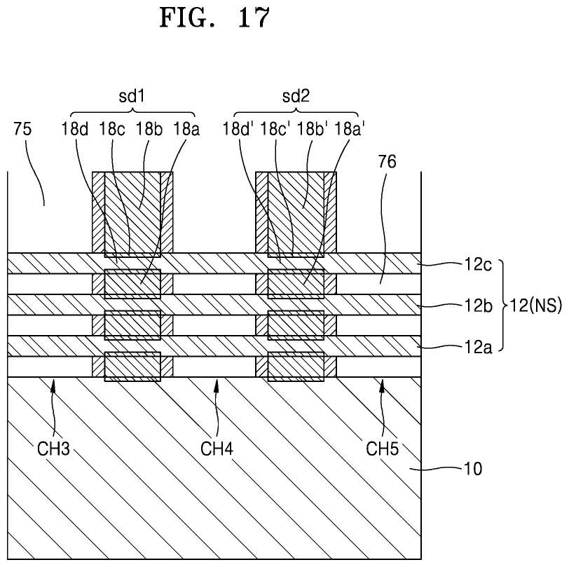

Referring to FIG. 17, third openings 75 are formed by removing the mask patterns 70. Fourth openings 76 are formed by etching the first to third sacrificial semiconductor layers 11a1, 11b1, and 11c1 that are positioned under the mask patterns 70. The fourth openings 76 are formed between the first to third nanosheet semiconductor layers 12a1, 12b1, and 12c1 by etching the first to third sacrificial semiconductor layers 11a1, 11b1, and 11c1 (refer to FIG. 16) that are positioned under the third openings 75.

The third openings 75 and the fourth openings 76 may be formed by simultaneously etching the mask patterns 70 and the first to third sacrificial semiconductor layers 11a1, 11b1, and 11c1. The third openings 75 and the fourth openings 76 may be formed through a wet etching process. The wet etching process may be performed using the etching selectivity of the first to third nanosheet semiconductor layers 12a1, 12b1, and 12c1 (refer to FIG. 16) and the etching selectivity of the first to third sacrificial semiconductor layers 11a1, 11b1, an d11c1 (refer to FIG. 16). The wet etching process may be performed using an etchant that etches the first to third sacrificial semiconductor layers 11a1, 11b1, and 11c1 (refer to FIG. 16) faster than the first third nanosheet semiconductor layers 12a1, 12b1, and 12c1 (refer to FIG. 16).

The third openings 75 and the fourth openings 76 may include a third region opening group CH3 formed in a third region, a fourth region opening group CH4 formed in a fourth region, and a fifth region opening group CH5 formed in a fifth region. Gate electrodes may be formed in the third to fifth region opening groups CH3, CH4, and CH5 through a subsequent process.

Nanosheets 12 (NS) may be formed from the nanosheet stack structure NSS by etching the first to third sacrificial semiconductor layers 11a1, 11b1, and 11c1 (refer to FIG. 16). The nanosheets 12 may include a first nanosheet 12a, a second nanosheet 12b, and a third nanosheet 12c.

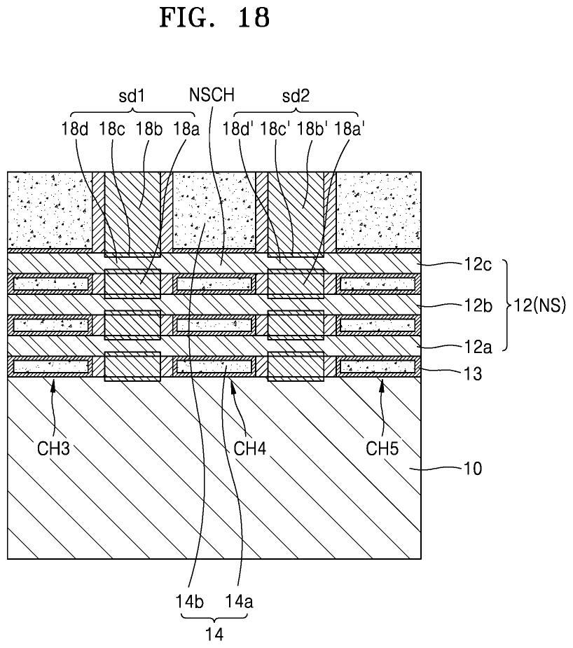

Referring to FIG. 18, gate insulating layers 13 and gate electrodes 14 are formed in the third region opening group CH3, the fourth region opening group CH4, and the fifth region opening group CH5. The gate insulating layers 13 may be formed on the nanosheets 12 in the third openings 75 and the fourth openings 76.

Each of the gate electrodes 14 may include lower gate electrodes 14a formed between the nanosheets 12, and an upper gate electrode 14b positioned on the third nanosheet 12c that is the uppermost nanosheet among the nanosheets 12. The nanosheets 12 may include channel regions NSCH on upper and lower portions of the gate electrodes 14. Through the processes described above, the integrated circuit semiconductor device TR1 may be manufactured.

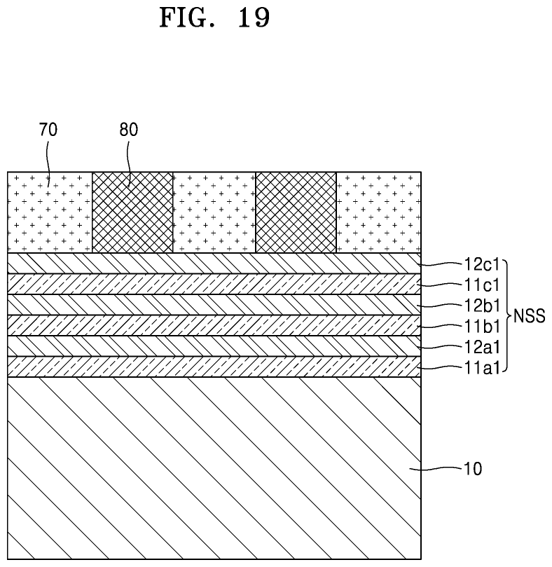

FIGS. 19 to 24 are cross-sectional views illustrating a method of manufacturing an integrated circuit semiconductor device, according to an example embodiment.

For example, FIGS. 19 to 24 illustrate a method of manufacturing the integrated circuit semiconductor device TR1 described with reference to FIGS. 1, 2A and 2B. The method shown in FIGS. 19 to 24 may be the same as the method described with reference to FIGS. 13 to 18 except the order of forming gate electrodes 24 and source/drain regions sd1 and sd2. Among the components shown in FIGS. 19 to 24, the same components as those shown in FIGS. 1, 2A, 2B, and 13 to 18 will be simply described or will not be described.

Referring to FIG. 19, a first sacrificial semiconductor layer 11a1, a first nanosheet semiconductor layer 12a1, a second sacrificial semiconductor layer 11b1, and a second nanosheet semiconductor layer 12b1, a third sacrificial semiconductor layer 11cl, and a third nanosheet semiconductor layer 12c1 are sequentially stacked on a substrate to form a nanosheet stack structure NSS. Mask patterns 70 are formed on the nanosheet stack structure NSS, and insulating patterns 80 are formed between the mask patterns 70.

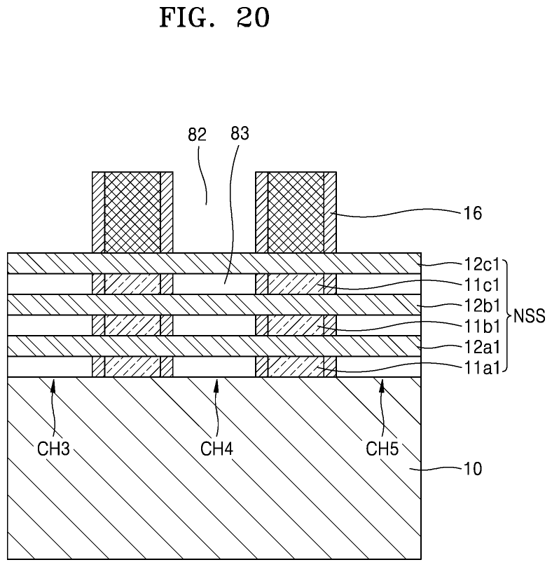

Referring to FIG. 20, third openings 82 are formed by removing the mask patterns 70. Fourth openings 83 are formed by etching the first to third sacrificial semiconductor layers 11a1, 11b1, and 11cl positioned under the mask patterns 70. The first to third sacrificial semiconductor layers 11a1, 11b1, and 11cl positioned below the third openings 82 are etched to form the fourth openings 83 between the first to third nanosheet semiconductor layers 12a1, 12b1, and 12c1.

The third openings 82 and the fourth openings 83 may be formed by simultaneously etching the mask patterns 70 and the first to third sacrificial semiconductor layers 11a1, 11b1, and 11cl. The third openings 82 and the fourth openings 83 may be formed through a wet etching process. The wet etching process may be performed using the etching selectivity of the first to third nanosheet semiconductor layers 12a1, 12b1, and 12c1, and the etching selectivity of the first to third sacrificial semiconductor layers 11a1, 11b1, and 11cl. The wet etching process may be performed using an etchant that etches the first to third sacrificial semiconductor layers 11a1, 11b1, and 11c1 faster than the first to third nanosheet semiconductor layers 12a1, 12b1, and 12c1.

The third openings 82 and the fourth openings 83 may include a third region opening group CH3 formed in a third region, a fourth region opening group CH4 formed in a fourth region, and a fifth region opening group CH5 formed in a fifth region. Gate electrodes may be formed in the third to fifth region opening groups CH3, CH4, and CH5 through a subsequent process.

Subsequently, spacers 16 are formed on inner sidewalls of the third openings 82 and the fourth openings 83. The spacers 16 may be formed by insulating layers such as silicon oxide layers or silicon nitride layers.

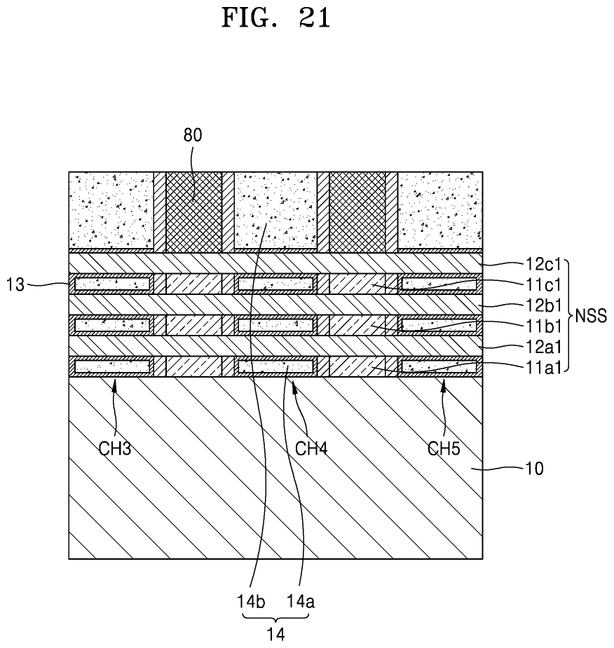

Referring to FIG. 21, gate insulating layers 13 and gate electrodes 14 are formed in the third region opening group CH3, the fourth region opening group CH4, and the fifth region opening group CH5. The gate insulating layers 13 may be formed in the third openings 82 and the fourth openings 83 on the first to third nanosheet semiconductor layers 12a1, 12b1, and 12c1.

Each of the gate electrodes 14 may include lower gate electrodes 14a formed between the first to third nanosheet semiconductor layers 12a1, 12b1, and 12c1, and an upper gate electrode 14b positioned on the third nanosheet semiconductor layer 12c1 that is the uppermost nanosheet semiconductor layer among the first to third nanosheet semiconductor layers 12a1, 12b1, and 12c1.

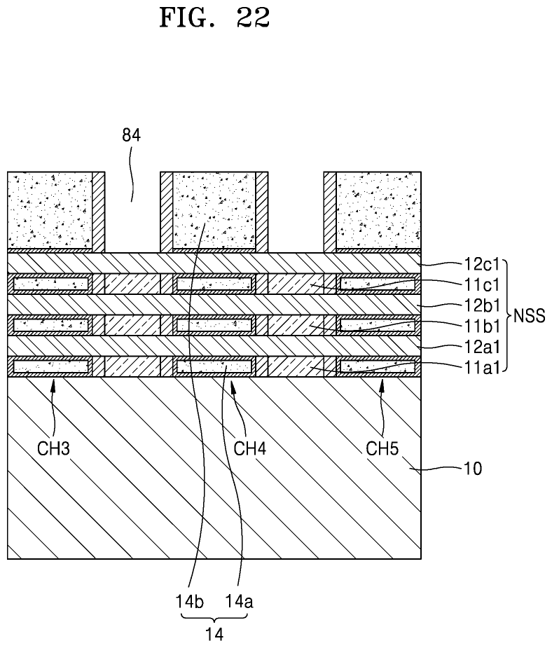

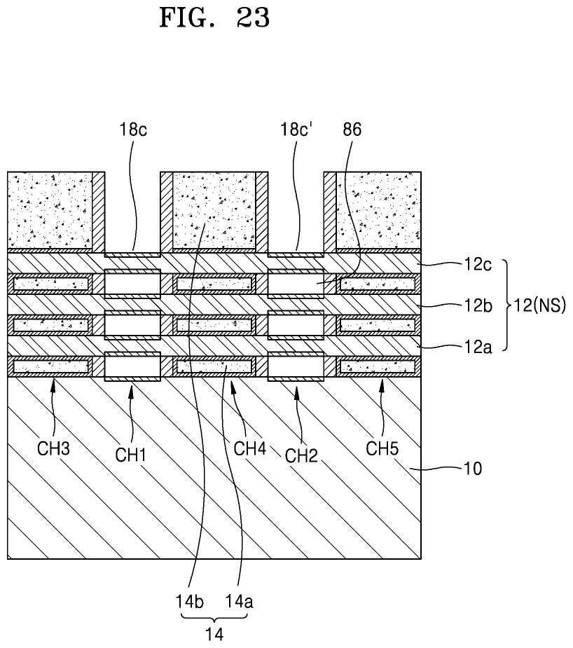

Referring to FIGS. 22 and 23, first openings 84 are formed by removing the insulating patterns 80 as shown in FIG. 22. Subsequently, as shown in FIG. 23, the first to third sacrificial semiconductor layers 11a1, 11b1, and 11c1 positioned below the first openings 84 are etched to form second openings 86 between the first to third nanosheet semiconductor layers 12a1, 12b1, and 12c1 (refer to FIG. 22). The second openings 86 may be formed using a wet etching process.

The wet etching process may be performed using the etching selectivity of the first to third nanosheet semiconductor layers 12a1, 12b1, and 12c1 (refer to FIG. 22), and the etching selectivity of the first to third sacrificial semiconductor layers 11a1, 11b1, and 11c1 (refer to FIG. 22). The wet etching process may be performed using an etchant that etches the first to third sacrificial semiconductor layers 11a1, 11b1, and 11c1 (refer to FIG. 22) faster than the first to third nanosheet semiconductor layers 12a1, 12b1, and 12c1 (refer to FIG. 22).

Nanosheets 12 (NS) may be formed from the nanosheet stack structure NSS by etching the first to third sacrificial semiconductor layers 11a1, 11b1, and 11c1 (refer to FIG. 22). The nanosheets 12 may include a first nanosheet 12a, a second nanosheet 12b, and a third nanosheet 12c.

The first openings 84 and the second openings 86 may include a first region opening group CHI formed in a first region and a second region opening group CH2 formed in a second region. Through a subsequent process, a first source/drain region may be formed in the first region opening group CH1, and a second source/drain region may be formed in the second region opening group CH2.

Subsequently, a dopant such as boron, arsenic, or phosphorus may be ion-implanted into the first to third nanosheets 12a, 12b, and 12c exposed through the first openings 84 and the second openings 86. The dopant is implanted into the first to third nanosheets 12a, 12b, and 12c exposed through the first region opening group CHI and the second region opening group CH2. The contact resistance of the source/drain regions may be reduced by implanting the dopant into the first to third nanosheets 12a, 12b, and 12c.

First and second silicide layers 18c and 18c′ are formed in surfaces of the first to third nanosheets 12a, 12b, and 12c that are exposed through the first openings 84 and the second openings 86. The first silicide layers 18c may be formed in the first region opening group CH1, and the second silicide layer 18c′ may be formed in the second region opening group CH2.

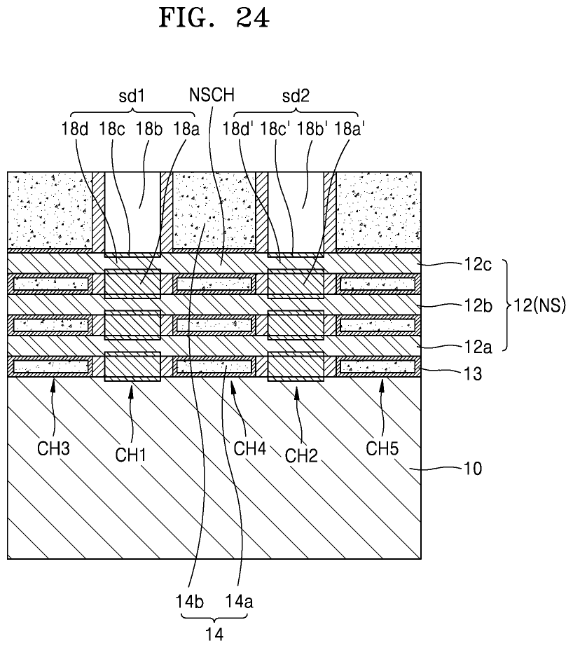

Referring to FIG. 24, first metal layers 18a and 18b and second metal layers 18a′ and 18b′ are formed inside the first openings 84 and the second openings 86. The first metal layers 18a and 18b and the second metal layers 18a′ and 18b′ may be formed on the spacers 16 and the first and second silicide layers 18c and 18c′.

The first metal layers 18a and 18b may be formed in the first region opening group CH1. The first metal layers 18a and 18b may include first lower metal layers 18a formed between the first to third nanosheets 12a, 12b, and 12c, and a first upper metal layer 18b positioned on the third nanosheet 12c that is the uppermost nanosheet among the first to third nanosheets 12a, 12b, and 12c.

The first lower metal layers 18a may be formed in the second openings 86 of the first region opening group CH1, and the first upper metal layer 18b may be formed in the first opening 84 of the first region opening group CH1. This process may be performed to form a first source/drain region sd1 including the first silicide layers 18c, the first metal layers 18a and 18b, and first nanosheet regions 18d positioned between the first silicide layer 18c. The first nanosheet regions 18d positioned between the first silicide layers 18c may be regions doped with the dopant such as boron, arsenic, or phosphorus.

The second metal layers 18a′ and 18b′ may be formed in the second region opening group CH2. The second metal layers 18a′ and 18b′ may include second lower metal layers 18a′ formed between the first to third nanosheets 12a, 12b, and 12c, and a second upper metal layer 18b′ positioned on the third nanosheet 12c that is the uppermost nanosheet among the first to third nanosheets 12a, 12b, and 12c.

The second lower metal layers 18a′ may be formed in the second openings 86 of the second region opening group CH2, and the second upper metal layer 18b′ may be formed in the first opening 84 of the second region opening group CH2. This process may be performed to form a second source/drain region sd2 including: second nanosheet regions 18d′ between the second silicide layers 18c′, the second metal layers 18a′ and 18b′, and the second silicide layers 18c′. The second nanosheet regions 18d′ positioned between the second silicide layers 18c′ may be regions doped with the dopant such as boron, arsenic, or phosphorus. In addition, the nanosheets 12 may include channel regions NSCH on upper and lower portions of the gate electrodes 14. Through the processes described above, the integrated circuit semiconductor device TR1 may be manufactured.

The integrated circuit semiconductor devices of the disclosure may include three-dimensional transistors each including source/drain regions of which the contact resistance is reduced. Therefore, the integrated circuit semiconductor devices of the disclosure may improve electrical characteristics of the three-dimensional transistors such as a short channel effect, and may further improve the current driving capability of the three-dimensional transistors.

While the disclosure has been particularly shown and described with reference to embodiments thereof, it will be understood that various changes in form and details may be made therein without departing from the spirit and scope of the following claims.

What is claimed is:

1. An integrated circuit semiconductor device comprising:
a nanosheet provided on a substrate, the nanosheet extending in a first horizontal direction;
a gate electrode comprising a first gate electrode portion provided on an upper side of the nanosheet and a second gate electrode portion provided on a lower side of the nanosheet, the gate electrode extending in a second horizontal direction that is perpendicular to the first horizontal direction;
a gate insulating layer provided between the gate electrode and the nanosheet;
a first source/drain region provided on a first side of the nanosheet corresponding to the gate electrode; and
a second source/drain region provided on a second side of the nanosheet corresponding to the gate electrode,
wherein the first source/drain region comprises:
first silicide layers comprising a first upper silicide layer provided on the nanosheet and extending inward from an upper surface of the nanosheet, and a first lower silicide layer on provided the nanosheet and extending inward from a lower surface of the nanosheet,
a first upper metal layer provided on the first upper silicide layer and a first lower metal layer provided on the first lower silicide layer, and
a first nanosheet region provided between the first upper silicide layer and the first lower silicide layer,
wherein the second source/drain region comprises:
second silicide layers comprising a second upper silicide layer provided on the nanosheet and extending inward from the upper surface of the nanosheet, and a second lower silicide layer provided on the nanosheet and extending inward from the lower surface of the nanosheet,
a second upper metal layer provided on the second upper silicide layer and a second lower metal layer provided on the second lower silicide layer, and
a second nanosheet region provided between the second upper silicide layer and the second lower silicide layer.

2. The integrated circuit semiconductor device of claim 1, wherein the nanosheet extends from the gate electrode to the first source/drain region in the first horizontal direction and extends from the gate electrode to the second source/drain region in a first reverse horizontal direction.

3. The integrated circuit semiconductor device of claim 1, wherein the nanosheet comprises a single layer which continuously extends in the first horizontal direction.

4. The integrated circuit semiconductor device of claim 1, wherein the nanosheet is spaced apart from a surface of the substrate, and a thickness of the nanosheet in a first vertical direction is greater than a thickness of the nanosheet in the second horizontal direction, the first vertical direction being perpendicular to the first and second horizontal directions.

5. The integrated circuit semiconductor device of claim 1, wherein the nanosheet has a first thickness in a first region between the first gate electrode portion and the second gate electrode portion and a second thickness in a second region between the first upper silicide layer and the first lower silicide layer or between the second upper silicide layer and the second lower silicide layer, the first thickness being different from the second thickness.

6. The integrated circuit semiconductor device of claim 1, wherein each of the first silicide layers and the second silicide layers comprises metal silicide layers or polycide layers.

7. The integrated circuit semiconductor device of claim 1, wherein the first source/drain region further comprises first metal liner layers provided on the first silicide layers, and the second source/drain region further comprises second metal liner layers provided on the second silicide layers.

8. The integrated circuit semiconductor device of claim 1, further comprising:
a first spacer provided between the gate electrode and the first source/drain region; and
a second spacer provided between the gate electrode and the second source/drain region.

9. The integrated circuit semiconductor device of claim 1, further comprising:
a through-electrode provided in the substrate and electrically connected to the first and second source/drain regions, and
a backside power rail provided in a back surface of the substrate electrically connected to the through-electrode.

10. The integrated circuit semiconductor device of claim 1, further comprising:
a first backside power rail provided in the substrate and electrically connected to the first and second source/drain regions,
a through-electrode provided in the substrate and electrically connected to the first backside power rail, and
a second backside power rail provided in a back surface of the substrate, and electrically connected to the through-electrode.

11. An integrated circuit semiconductor device comprising:
a plurality of nanosheets provided on a substrate, the plurality of nanosheets extending in a first horizontal direction and being spaced apart from a surface of the substrate and spaced apart from each other in a first vertical direction that is perpendicular to the first horizontal direction;
a gate electrode comprising a plurality of gate electrode portions provided on the plurality of nanosheets, the gate electrode extending in a second horizontal direction that is perpendicular to the first horizontal direction;
a plurality of gate insulating layers provided between the plurality of gate electrode portions and the plurality of nanosheets;
a first source/drain region provided on a first side of the plurality of nanosheets corresponding to the gate electrode; and
a second source/drain region provided on a second side of the plurality of nanosheets corresponding to the gate electrode,
wherein the first source/drain region comprises:
first silicide layers comprising a first upper silicide layer provided on a first nanosheet, among the plurality of nanosheets, and extending inward from an upper surface of the first nanosheet, and a first lower silicide layer on provided the first nanosheet and extending inward from a lower surface of the first nanosheet,
a first upper metal layer provided on the first upper silicide layer,
a first lower metal layer provided on the first lower silicide layer, and
a first nanosheet region provided between the first upper silicide layer and the first lower silicide layer, and
wherein the second source/drain region comprises:
second silicide layers comprising a second upper silicide layer provided on the first nanosheet and extending inward from the upper surface of the first nanosheet, and a second lower silicide layer provided on the first nanosheet and extending inward from the lower surface of the first nanosheet,
a second upper metal layer provided on the second upper silicide layer,
a second lower metal layer provided on the second lower silicide layer, and
a second nanosheet region provided between the second upper silicide layer and the second lower silicide layer.

12. The integrated circuit semiconductor device of claim 11, wherein each of the plurality of nanosheets comprises a single layer continuously extending from the gate electrode to the first source/drain region in the first horizontal direction and continuously extending from the gate electrode to the second source/drain region in a first reverse horizontal direction.

13. The integrated circuit semiconductor device of claim 11, wherein each of the first source/drain region and the second source/drain region comprise non-epitaxial growth layers.

14. The integrated circuit semiconductor device of claim 11, wherein the first upper metal layer is provided above the first nanosheet, which is an uppermost nanosheet among the plurality of nanosheets, and
wherein the first lower metal layer provided on the first nanosheet and a second nanosheet, among the plurality of nanosheets.

15. The integrated circuit semiconductor device of claim 11, further comprising:
channel regions in the plurality of nanosheets between the plurality of gate electrode portions, and
non-channel regions in the plurality of nanosheets between the first upper silicide layer and the first lower silicide layer or between the second upper silicide layer and the second lower silicide layer, the—channel regions being in contact with the first and second source/drain regions.

16. The integrated circuit semiconductor device of claim 11, further comprising:
a first spacer provided between the gate electrode and the first source/drain region; and
a second spacer provided between the gate electrode and the second source/drain region.

17. The integrated circuit semiconductor device of claim 11, further comprising:
a through-electrode formed in the substrate, the through-electrode being electrically connected to a backside power rail electrically connected to the first and second source/drain regions, and
contact electrodes connected to a wiring layer, the contact electrodes being formed in the first and second source/drain regions.

18. An integrated circuit semiconductor device comprising:
a lower nanosheet provided on a substrate, the lower nanosheet extending in a first horizontal direction;
an upper nanosheet provided on the substrate, the upper nanosheet extending in the first horizontal direction and being apart from a surface of the substrate in a first vertical direction that is perpendicular to the first horizontal direction;
an isolation-insulating layer configured to insulate the lower nanosheet and the upper nanosheet from each other;
a gate electrode comprising a plurality of gate electrode portions provided on the upper and lower nanosheets, the gate electrode extending in a second horizontal direction perpendicular to the first horizontal direction;
a first source/drain region provided on a first side of the lower and upper nanosheets corresponding to the gate electrode; and
a second source/drain region formed on a second side of the lower and upper nanosheets with corresponding to the gate electrode,
wherein the first source/drain region comprises:
first silicide layers comprising a first upper silicide layer provided on the lower nanosheet and upper nanosheet and extending inward from an upper surface of the lower nanosheet and upper nanosheet, and a first lower silicide layer on provided the lower nanosheet and upper nanosheet and extending inward from a lower surface of the lower nanosheet and upper nanosheet,
a first upper metal layer provided on the first upper silicide layer,
a first lower metal layer provided on the first lower silicide layer, and
a first nanosheet region provided between the first upper silicide layer and the first lower silicide layer, and
wherein the second source/drain region comprises:
second silicide layers comprising a second upper silicide layer provided on the lower nanosheet and upper nanosheet and extending inward from the upper surface of the lower nanosheet and upper nanosheet, and a second lower silicide layer provided on the lower nanosheet and upper nanosheet and extending inward from the lower surface of the lower nanosheet and upper nanosheet,
a second upper metal layer provided on the second upper silicide layer,
a second lower metal layer provided on the second lower silicide layer, and
a second nanosheet region provided between the second upper silicide layer and the second lower silicide layer.

19. The integrated circuit semiconductor device of claim 18, wherein each of the upper nanosheet and the lower nanosheet comprises a single layer which continuously extends from the gate electrode to the first source/drain region in the first horizontal direction and extends from the gate electrode to the second source/drain region in a first reverse horizontal direction.

20. The integrated circuit semiconductor device of claim 18, further comprising:
a first spacer provided between the gate electrode and the first source/drain region;
a second spacer provided between the gate electrode and the second source/drain region,
wherein the isolation-insulating layer divides the plurality of gate electrode portions in the first vertical direction into first gate electrode portions corresponding to the lower nanosheet and second gate electrode portions corresponding to the upper nanosheet, and
wherein the isolation-insulating layer separates the first upper and lower metal layers and the second upper and lower metal layers.
